(19) United States
(12) Patent Application Publication
(10) Pub. No.: US 2025/0176190 A1
(43) Pub. Date: May 29, 2025

(54) STORAGE DEVICE

(71) Applicant: Semiconductor Energy Laboratory Co., Ltd., Atsugi-shi, Kanagawa-ken (JP)

(72) Inventors: Hitoshi KUNITAKE, Machida (JP); Fumito ISAKA, Zama (JP); Tatsuya ONUKI, Atsugi (JP); Shunpei YAMAZAKI, Setagaya (JP)

(21) Appl. No.: 18/838,670

(22) PCT Filed: Feb. 10, 2023
(86) PCT No.: PCT/IB2023/051189

§ 371 Date: Aug. 15, 2024

(30) Foreign Application Priority Data
Feb. 25, 2022 (JP) 2022-027682

(51) Int. Cl. H10B 51/30; H10B 51/10; H10B 53/10; H10B 53/30; H10D 1/68; H10D 30/67; H10D 30/69

(52) U.S. Cl. CPC H10B 51/30; H10B 51/10; H10B 53/10; H10B 53/30; H10D 1/692; H10D 30/6755; H10D 30/701

(57) ABSTRACT

A storage device including a novel semiconductor device is provided. The storage device includes a memory cell including a transistor and a capacitor, and a conductor. The transistor includes one of a source electrode and a drain electrode, the other of the source electrode and the drain electrode, a first gate insulator, and a first gate electrode. The capacitor includes one electrode, a dielectric placed over the one electrode, and the other electrode placed over the dielectric. The top surface and the side surface of the one of the source electrode and the drain electrode of the transistor are in contact with the conductor, and the top surface of the other of the source electrode and the drain electrode of the transistor is in contact with the one electrode of the capacitor. The dielectric includes a ferroelectric material.

### TECHNICAL FIELD

One embodiment of the present invention relates to a transistor, a semiconductor device, a storage device, and an electronic appliance. Another embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed, and LSIs, CPUs, memories, and the like are mainly used as semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of a transistor using an oxide semiconductor. Furthermore, for example, Patent Document 2 discloses a storage device that can retain stored contents for a long time by utilizing a feature of a low leakage current of the transistor including an oxide semiconductor.

In recent years, demand for an integrated circuit with higher density has risen with reductions in size and weight of electronic appliances. In addition, the improvement of productivity of semiconductor devices including an integrated circuit has been desired. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

In addition, memories under development employ various memory systems for intended uses such as temporary storage at the time of executing arithmetic processing and long-term storage of data. Examples of memories with typical memory systems include a DRAM (Dynamic Random Access Memory), an SRAM (Static Random Access Memory), and a flash memory.

In addition to the above, memories using ferroelectrics have been actively researched and developed as disclosed in Non-Patent Document 2. For the next-generation ferroelectric memories, researches on hafnium oxides, such as research on ferroelectric HfO₂-based materials (Non-Patent Document 3); research on ferroelectricity of a hafnium oxide thin film (Non-Patent Document 4); research on ferroelectricity of a HfO2 thin film (Non-Patent Document 5); and demonstration of integration of a FeRAM using a ferroelectric Hf_{0.5}Zr_{0.5}O₂ and a CMOS (Non-Patent Document 6) have been actively carried out.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53
[Non-Patent Document 2] T. S. Boescke, et al, “Ferroelectricity in hafnium oxide thin films”, APL99, 2011
[Non-Patent Document 3] Zhen Fan, et al, “Ferroelectric HfO₂-based materials for next-generation ferroelectric memories”, JOURNAL OF ADVANCED DIELECTRICS, Vol. 6, No. 2, 2016
[Non-Patent Document 4] Jun Okuno, et al, “SoC compatible 1T1C FeRAM memory array based on ferroelectric Hf_{0.5}Zr_{0.5}O₂”, VLSI 2020
[Non-Patent Document 5] Akira Toriumi, “Ferroelectric properties of thin HfO₂ films”, the Japan Society of Applied Physics, Vol. 88, No. 9, 2019
[Non-Patent Document 6] T. Francois, et al, “Demonstration of BEOL-compatible ferroelectric Hf_{0.5}Zr_{0.5}O₂ scaled FeRAM co-integrated with 130 nm CMOS for embedded NVM applications”, IEDM 2019

### SUMMARY OF THE INVENTION

### Problems to be Solved by the Invention

An object of one embodiment of the present invention is to provide a semiconductor device that can be reduced in size or can be highly integrated. Another object is to provide a semiconductor device that operates at high speed. Another object is to provide a semiconductor device having good electrical characteristics. Another object is to provide a semiconductor device with a small variation in electrical characteristics of transistors. Another object is to provide a semiconductor device having high reliability. Another object is to provide a semiconductor device with a high on-state current. Another object is to provide a semiconductor device with low power consumption. Another object is to provide a novel semiconductor device. Another object is to provide a storage device including a novel semiconductor device.

Note that the description of these objects does not preclude the existence of other objects. One embodiment of the present invention does not need to achieve all the objects. Note that other objects will be apparent from the description of the specification, the drawings, the claims, and the like, and other objects can be derived from the description of the specification, the drawings, the claims, and the like.

### Means for Solving the Problems

One embodiment of the present invention is a storage device including a memory cell including a transistor and a capacitor, and a conductor. The transistor includes one of a source electrode and a drain electrode, the other of the source electrode and the drain electrode, a first gate insulator, and a first gate electrode. The capacitor includes one electrode, a dielectric placed over the one electrode, and the other electrode placed over the dielectric. The top surface and the side surface of the one of the source electrode and the drain electrode of the transistor are in contact with the conductor. The top surface of the other of the source electrode and the drain electrode of the transistor is in contact with the one electrode of the capacitor. The dielectric includes a ferroelectric material.

In the above, the dielectric of the capacitor preferably includes hafnium, zirconium, and oxygen.

In the above, the dielectric of the capacitor preferably includes aluminum, scandium, and nitrogen.

In the above, the transistor preferably includes an oxide semiconductor.

In the above, the transistor preferably includes a second gate insulator and a second gate electrode, a top surface of the second gate insulator of the transistor preferably is in contact with part of the other of the source electrode and the drain electrode of the transistor, and the second gate electrode of the transistor is preferably placed to overlap with the first gate electrode of the transistor with the second gate insulator of the transistor therebetween.

In the above, the storage device preferably includes a plurality of layers each including the memory cell and the conductor, the layers are preferably stacked, and the conductors in the layers preferably overlap with each other.

### Effect of the Invention

One embodiment of the present invention can provide a semiconductor device that can be reduced in size or can be highly integrated. A semiconductor device that operates at high speed can be provided. A semiconductor device having good electrical characteristics can be provided. A semiconductor device with a small variation in electrical characteristics of transistors can be provided. A semiconductor device having high reliability can be provided. A semiconductor device with a high on-state current can be provided. A semiconductor device with low power consumption can be provided. A novel semiconductor device can be provided. A storage device including a novel semiconductor device can be provided.

Note that the description of these effects does not preclude the existence of other effects. One embodiment of the present invention does not have to have all these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a top view of a semiconductor device. FIG. 1B to FIG. 1D are cross-sectional views of the semiconductor device.

FIG. 2 is a circuit diagram illustrating a structure of a storage device.

FIG. 3A and FIG. 3B are cross-sectional views of a semiconductor device.

FIG. 4A and FIG. 4B are cross-sectional views of a semiconductor device.

FIG. 5A to FIG. 5C are cross-sectional views of a semiconductor device.

FIG. 6A is a top view of a semiconductor device. FIG. 6B to FIG. 6D are cross-sectional views of the semiconductor device.

FIG. 7A and FIG. 7B are cross-sectional views of a semiconductor device.

FIG. 8 is a cross-sectional view of a semiconductor device.

FIG. 9A is a diagram illustrating an example of a circuit structure of a memory cell. FIG. 9B is a graph showing an example of hysteresis characteristics. FIG. 9C is a timing chart showing a driving method of a memory cell.

FIG. 10A to FIG. 10C are diagrams illustrating a structure example of a storage device.

FIG. 11A is a diagram illustrating a structure example of a storage device.

FIG. 11B is a schematic diagram of a memory string included in the storage device.

FIG. 12A is a diagram illustrating a structure example of a storage device.

FIG. 12B is a schematic diagram of a memory string included in the storage device.

FIG. 13 is a layout diagram illustrating a structure of a storage device.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

Furthermore, especially in a top view (also referred to as a “plan view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in this specification, the description can be changed appropriately depending on the situation.

For example, in this specification and the like, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) exists between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, an oxynitride is a material that contains more oxygen than nitrogen in its composition. Moreover, a nitride oxide is a material that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

### Embodiment 1

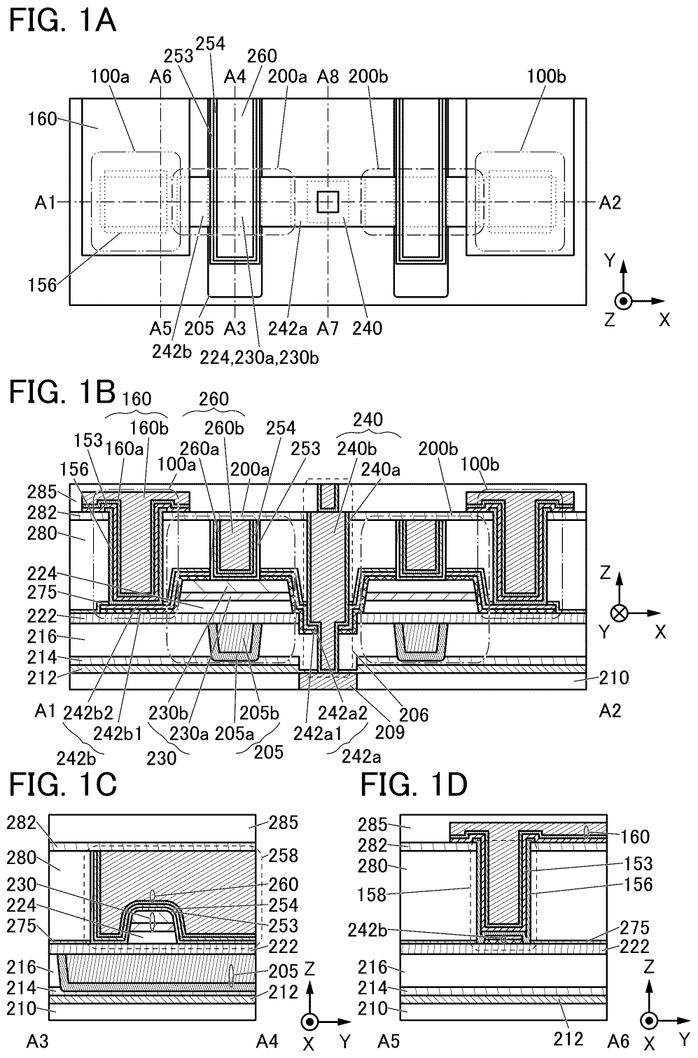

In this embodiment, an example of a semiconductor device of one embodiment of the present invention will be described with reference to FIG. 1 to FIG. 9. The semiconductor device of one embodiment of the present invention includes a transistor and a capacitor including a ferroelectric.

### Structure Example of Semiconductor Device

A structure of a semiconductor device including a transistor and a capacitor will be described with reference to FIG. 1. FIG. 1A to FIG. 1D are a top view and cross-sectional views of a semiconductor device including a transistor 200a, a transistor 200b, a capacitor 100a, and a capacitor 100b. FIG. 1A is a top view of the semiconductor device. FIG. 1B to FIG. 1D are cross-sectional views of the semiconductor device. Here, FIG. 1B is a cross-sectional view of a portion indicated by a dashed-dotted line A1-A2 in FIG. 1A, and is also a cross-sectional view of the transistor 200a and the transistor 200b in the channel length direction. FIG. 1C is a cross-sectional view of a portion indicated by a dashed-dotted line A3-A4 in FIG. 1A, and is also a cross-sectional view of the transistor 200a in the channel width direction. FIG. 1D is a cross-sectional view of a portion indicated by a dashed-dotted line A5-A6 in FIG. 1A, and is also a cross-sectional view of the capacitor 100a in the direction parallel to the channel width direction of the transistor 200a and the transistor 200b. Note that for clarity of the drawing, some components are omitted in the top view of FIG. 1A.

The X direction shown in FIG. 1A is parallel to the channel length direction of the transistor 200a and the channel length direction of the transistor 200b, the Y direction is perpendicular to the X direction, and the Z direction is perpendicular to the X direction and the Y direction. Note that the X direction, the Y direction, and the Z direction shown in FIG. 1A are also shown in FIG. 1B to FIG. 1D.

The semiconductor device of one embodiment of the present invention includes an insulator 214 over a substrate (not illustrated); the transistor 200a, the transistor 200b, the capacitor 100a, and the capacitor 100b over the insulator 214; an insulator 280 over an insulator 275 provided in the transistor 200a and the transistor 200b; an insulator 282 over the insulator 280; an insulator 285 over the capacitor 100a, the capacitor 100b, and the insulator 282; and a conductor 240 (a conductor 240a and a conductor 240b). The insulator 214, the insulator 280, the insulator 282, and the insulator 285 each function as an interlayer film. As illustrated in FIG. 1B, at least part of each of the transistor 200a, the transistor 200b, the capacitor 100a, and the capacitor 100b is provided to be embedded in the insulator 280.

Here, the transistor 200a and the transistor 200b each include an oxide 230 functioning as a semiconductor layer, a conductor 260 functioning as a first gate (also referred to as top gate) electrode, a conductor 205 functioning as a second gate (also referred to as back gate) electrode, a conductor 242a functioning as one of a source electrode and a drain electrode, and a conductor 242b functioning as the other of the source electrode and the drain electrode. An insulator 253 and an insulator 254 functioning as a first gate insulator are also included. An insulator 222 and an insulator 224 functioning as a second gate insulator are also included. Note that the gate insulator is also referred to as a gate insulating layer or a gate insulating film in some cases.

The transistor 200a and the transistor 200b have the same structure; thus, in the following description on matters that are common to the transistor 200a and the transistor 200b, the alphabets added to the reference numerals are omitted and the term “transistor 200” is used in some cases.

The first gate electrode and the first gate insulator of the transistor 200 are placed in an opening 258 (see FIG. 1C) formed in the insulator 280 and the insulator 275. That is, the conductor 260, the insulator 254, and the insulator 253 are each placed inside the opening 258.

The capacitor 100a and the capacitor 100b each include a conductor 156 functioning as a lower electrode, an insulator 153 functioning as a dielectric, and a conductor 160 functioning as an upper electrode. In other words, the capacitor 100a and the capacitor 100b each form a MIM (Metal-Insulator-Metal) capacitor.

The capacitor 100a and the capacitor 100b have the same structure; thus, in the following description on matters that are common to the capacitor 100a and the capacitor 100b, the alphabets added to the reference numerals are omitted and the term “capacitor 100” is used in some cases.

Parts of the upper electrode, the dielectric, and the lower electrode of the capacitor 100 are placed in an opening 158 (see FIG. 1D) formed in the insulator 282, the insulator 280, and the insulator 275. That is, the conductor 160, the insulator 153, and the conductor 156 are placed in the opening 158.

The semiconductor device of one embodiment of the present invention also includes a conductor 240 (a conductor 240a and a conductor 240b) electrically connected to the transistor 200 and functioning as a plug (also can be referred to as a connection electrode). The conductor 240 is placed in an opening 206 (see FIG. 1B) formed in the insulator 280 and the like. The conductor 240 includes a region in contact with part of the top surface of the conductor 242a and part of the side surface of the conductor 242a.

In addition, the semiconductor device of one embodiment of the present invention includes an insulator 210 and a conductor 209 between the substrate (not illustrated) and the insulator 214. The conductor 209 is provided to be embedded in the insulator 210. The conductor 209 includes a region in contact with the conductor 240.

The semiconductor device of one embodiment of the present invention may include an insulator 212 between the insulator 210 and the insulator 214 and between the conductor 209 and the insulator 214.

The semiconductor device including the transistor 200 and the capacitor 100 described in this embodiment can be used as a memory cell of a storage device. In that case, the conductor 240 is electrically connected to a sense amplifier in some cases, and the conductor 240 functions as a bit line. Here, as illustrated in FIG. 1A, the capacitor 100 is provided such that at least part of the capacitor 100 overlaps with the conductor 242b included in the transistor 200. Thus, the capacitor 100 can be provided without significantly increasing the area occupied by the semiconductor device in the plan view, so that the semiconductor device according to this embodiment can be miniaturized or highly integrated.

In addition, the semiconductor device including the transistor 200 and the capacitor 100 described in this embodiment includes a ferroelectric in the capacitor 100, as mentioned above. Thus, in the case where the semiconductor device is used as a memory cell of a storage device, the semiconductor device can function as a nonvolatile storage element that can retain written data even when power supply is stopped. Furthermore, a DRAM without a ferroelectric in its capacitor requires regular refresh operations, which leads to an increase in power consumption. However, since the semiconductor device described in this embodiment includes a ferroelectric in the capacitor, a refresh operation is unnecessary, and the power consumption can be reduced as compared with a DRAM without a ferroelectric in its capacitor.

The semiconductor device described in this embodiment has a line-symmetric structure with respect to dashed-dotted line A7-A8 illustrated in FIG. 1A. In other words, it can be said that the transistor 200a and the transistor 200b are placed line-symmetrically with respect to the conductor 240 as the symmetric axis, as illustrated in FIG. 1B. It can also be said that the capacitor 100a and the capacitor 100b are placed line-symmetrically with respect to the conductor 240 as the symmetrical axis. Here, the conductor 242a functions as one of a source electrode and a drain electrode of the transistor 200a and one of a source electrode and a drain electrode of the transistor 200b. The transistor 200a and the transistor 200b share the conductor 240 functioning as a plug. In this manner, when the connection of the two transistors, the two capacitors, and the plug have the above-described structure, a semiconductor device that can be miniaturized or highly integrated can be provided.

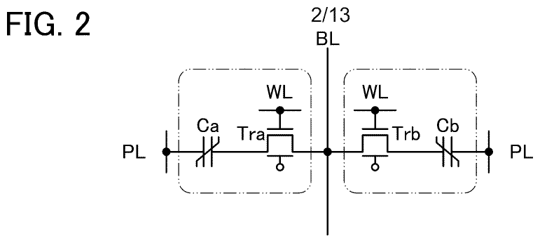

FIG. 2 shows a circuit diagram of a case where the semiconductor device described in this embodiment is used for a storage device. The semiconductor device including the transistor 200a and the capacitor 100a can be used as a memory cell of the storage device. In addition, the semiconductor device including the transistor 200b and the capacitor 100b can be used as a memory cell of the storage device.

As illustrated in FIG. 2, the semiconductor device illustrated in FIG. 1A to FIG. 1D can be referred to as a storage device that is composed of two memory cells. One memory cell includes a transistor Tra and a capacitor Ca. The other memory cell includes a transistor Trb and a capacitor Cb.

Here, the transistor Tra, the transistor Trb, the capacitor Ca, and the capacitor Cb correspond to the transistor 200a, the transistor 200b, the capacitor 100a, and the capacitor 100b, respectively.

In the one memory cell, one of a source and a drain of the transistor Tra is connected to a wiring BL. The other of the source and the drain of the transistor Tra is connected to one electrode of the capacitor Ca. A gate of the transistor Tra is connected to a wiring WL. The other electrode of the capacitor Ca is connected to a wiring PL.

In the other memory cell, one of a source and a drain of the transistor Trb is connected to the wiring BL. The other of the source and the drain of the transistor Trb is connected to one electrode of the capacitor Cb. A gate of the transistor Trb is connected to a wiring WL. The other electrode of the capacitor Cb is connected to a wiring PL.

Note that the memory cell will be described in detail in a later embodiment.

### Transistor 200

As illustrated in FIG. 1A to FIG. 1D, the transistor 200 includes an insulator 216 over the insulator 214, the conductor 205 (a conductor 205a and a conductor 205b) placed to be embedded in the insulator 216, the insulator 222 over the insulator 216 and the conductor 205, the insulator 224 over the insulator 222, an oxide 230a over the insulator 224, an oxide 230b over the oxide 230a, the conductor 242a (a conductor 242a1 and a conductor 242a2) and the conductor 242b (a conductor 242b1 and a conductor 242b2) over the oxide 230b, the insulator 253 over the oxide 230b, the insulator 254 over the insulator 253, the conductor 260 (a conductor 260a and a conductor 260b) positioned over the insulator 254 and overlapping with part of the oxide 230b, and the insulator 275 placed over the insulator 222, the insulator 224, the oxide 230a, the oxide 230b, the conductor 242a, and the conductor 242b.

Note that in this specification and the like, the oxide 230a and the oxide 230b are collectively referred to as the oxide 230 in some cases. The conductor 242a and the conductor 242b are also collectively referred to as the conductor 242 in some cases.

The opening 258 reaching the oxide 230b is provided in the insulator 280 and the insulator 275. That is, it can be said that the opening 258 includes a region overlapping with the oxide 230b. It can be said that the insulator 275 includes an opening overlapping with an opening included in the insulator 280. In other words, the opening 258 includes an opening included in the insulator 280 and an opening included in the insulator 275. The insulator 253, the insulator 254, and the conductor 260 are placed in the opening 258. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor 200. The insulator 254 includes a region in contact with the side surface of the conductor 260 and a region in contact with the bottom surface of the conductor 260. As illustrated in FIG. 1C, the top surface of the insulator 222 is exposed in a region of the opening 258 that does not overlap with the oxide 230.

The oxide 230 preferably includes the oxide 230a placed over the insulator 224 and the oxide 230b placed over the oxide 230a. With the oxide 230a positioned under the oxide 230b, diffusion of impurities from components formed below the oxide 230a into the oxide 230b can be inhibited.

Although an example of a structure in which two layers, the oxide 230a and the oxide 230b, are stacked as the oxide 230 in the transistor 200 is described, the present invention is not limited thereto. For example, the oxide 230 may be provided as a single layer of the oxide 230b or to have a stacked-layer structure of three or more layers, or the oxide 230a and the oxide 230b may each have a stacked-layer structure.

In the transistor 200, the conductor 260 functions as a first gate, and the conductor 205 functions as a second gate electrode. The insulator 253 and the insulator 254 function as a first gate insulator, and the insulator 222 and the insulator 224 function as a second gate insulator. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

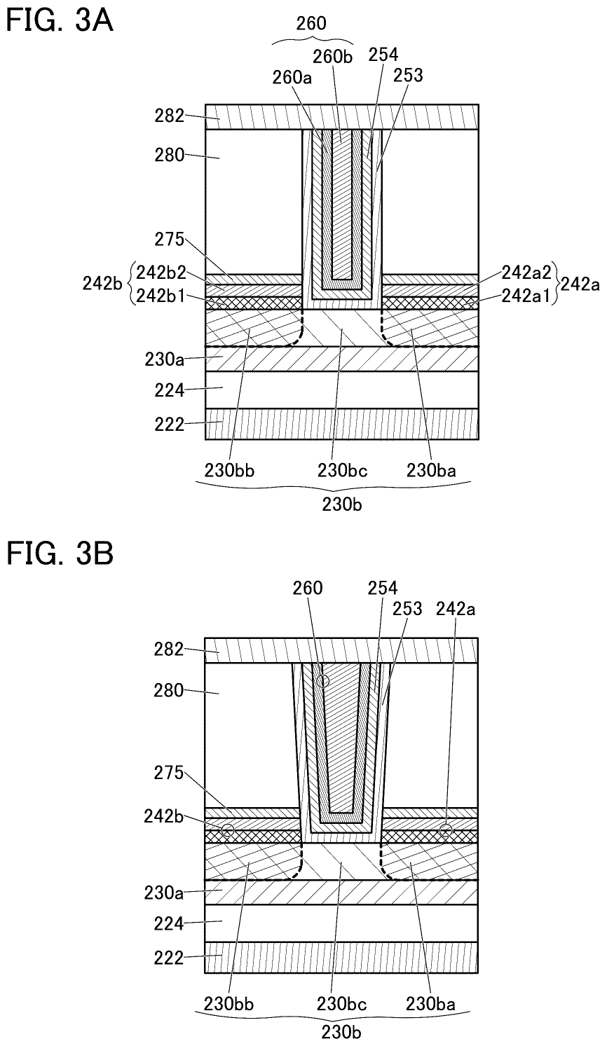

FIG. 3A is an enlarged view of the vicinity of the channel formation region in FIG. 1B. As illustrated in FIG. 3A and FIG. 1C, the opening 258 can also be regarded as having a shape in which part of a structure body formed of the insulator 224 and the oxide 230 protrudes into the opening having the insulator 222 as the bottom surface and the insulator 280 and the insulator 275 as the side surface.

As illustrated in FIG. 3A and FIG. 1C, the insulator 253 is provided in contact with the bottom surface and the inner wall (also referred to as sidewall) of the opening 258. Thus, the insulator 253 is in contact with at least parts of the top surface of the insulator 222, the side surface of the insulator 224, the side surface of the oxide 230a, the top surface and the side surface of the oxide 230b, side surfaces of the conductor 242a and the conductor 242b, the side surface of the insulator 275, the side surface of the insulator 280, and the bottom surface of the insulator 254.

As illustrated in FIG. 3A, the width of the transistor 200 in the channel length direction in the opening 258 is substantially the same as the distance between the conductor 242a and the conductor 242b. Thus, the channel formation region is formed in a region of the oxide 230b that overlaps with the width of the transistor 200 in the channel length direction in the opening 258. Here, the distance between the conductor 242a and the conductor 242b is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. When the channel formation region of the transistor 200 has such a very minute structure in this way, the on-state current of the transistor 200 can be increased and the frequency characteristics can be improved. In addition, it becomes possible to provide a plurality of the transistors 200 with high density in a small area. However, without limitation to the above, the distance between the conductor 242a and the conductor 242b can be greater than or equal to 60 nm.

Furthermore, miniaturization of the transistor 200 can improve high-frequency characteristics. Specifically, a cutoff frequency can be improved. When the gate length of the transistor 200 is within any of the above ranges, the cutoff frequency of the transistor 200 can be greater than or equal to 50 GHz or greater than or equal to 100 GHz at room temperature, for example.

Although FIG. 3A illustrates a structure in which the sidewall of the opening 258 is substantially perpendicular to the top surface of the insulator 222, the present invention is not limited thereto. As illustrated in FIG. 3B, the sidewall of the opening 258 may have a tapered shape. When the sidewall of the opening 258 has a tapered shape, the coverage with the insulator 253 and the like can be improved in a later step, so that defects such as a void can be reduced.

Note that in this specification and the like, a tapered shape refers to a shape such that at least part of the side surface of a structure is inclined with respect to a substrate surface or a formation surface. For example, the tapered shape refers to a shape including a region where the angle formed by the inclined side surface and the substrate surface or the formation surface (hereinafter, such an angle is also referred to as a taper angle in some cases) is less than 90°. Note that the side surface and the substrate surface or the formation surface of the component are not necessarily completely flat, and may have a substantially planar shape with a small curvature or a substantially planar shape with slight unevenness.

As illustrated in FIG. 3A, the oxide 230b includes a region 230bc functioning as the channel formation region of the transistor 200 and a region 230ba and a region 230bb that are provided to sandwich the region 230bc and function as the source region or the drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than those of the region 230ba and the region 230bb, and thus is a high-resistance region with a low carrier concentration. Thus, the region 230bc can be regarded as being i-type (intrinsic) or substantially i-type. The region 230ba and the region 230bb functioning as the source region and the drain region include a large amount of oxygen vacancies or have a high concentration of an impurity such as hydrogen, nitrogen, or a metal element, and thus are each a low-resistance region with an increased carrier concentration. In other words, the region 230ba and the region 230bb are each an n-type region having a higher carrier concentration and a lower resistance than the region 230bc.

Here, as illustrated in FIG. 3A, the side surfaces of the conductor 242a and the conductor 242b that face each other are preferably substantially perpendicular to the top surface of the oxide 230b. With such a structure, the side end portion of the region 230ba on the region 230bc side that is formed under the conductor 242a can be inhibited from excessively receding from the side end portion of the conductor 242a on the region 230bc side. Similarly, the side end portion of the region 230bb on the region 230bc side that is formed under the conductor 242b can be inhibited from excessively receding from the side end portion of the conductor 242b on the region 230bc side. This can inhibit formation of what is called a Loff region between the region 230ba and the region 230bc and between the region 230bb and the region 230bc. Here, when the side end portion of the region 230ba on the region 230bc side recedes, the side end portion of the region 230ba is positioned closer to the conductor 240 shown in FIG. 1B and the like than the side surface of the conductor 242a on the region 230bc side is. In addition, when the side end portion of the region 230bb on the region 230bc side recedes, the side end portion of the region 230bb is positioned closer to the conductor 160 shown in FIG. 1B and the like than the side surface of the conductor 242b on the region 230bc side is.

Accordingly, the frequency characteristics of the transistor 200 can be improved, and the operation speed of the semiconductor device of one embodiment of the present invention can be improved. For example, in the case where the semiconductor device of one embodiment of the present invention is used as a memory cell of a storage device, the writing speed and the reading speed can be improved.

Note that the carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. The lower limit of the carrier concentration in the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations in the region 230ba and the region 230bb and higher than or substantially equal to the carrier concentration in the region 230bc may be formed. That is, the region functions as a junction region between the region 230bc and the region 230ba or the region 230bb. The hydrogen concentration in the junction region is lower than or substantially equal to the hydrogen concentrations in the region 230ba and the region 230bb and higher than or substantially equal to the hydrogen concentration in the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 3A illustrates an example where the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentration of a metal element and an impurity element such as hydrogen and nitrogen, which is detected in each region, may be not only gradually changed between the regions but also continuously changed in each region. That is, the region closer to the channel formation region preferably has a lower concentration of a metal element and an impurity element such as hydrogen and nitrogen.

In the transistor 200, a metal oxide functioning as a semiconductor (such a metal oxide is hereinafter also referred to as an oxide semiconductor) is preferably used for the oxide 230 (the oxide 230a and the oxide 230b) including the channel formation region.

As the oxide 230, a metal oxide such as indium oxide, gallium oxide, or zinc oxide is preferably used, for example. As the metal oxide 230, a metal oxide that contains two or three selected from indium, the element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin. Note that a metal oxide containing indium, the element M, and zinc is referred to as In-M-Zn oxide in some cases.

The oxide 230 preferably has a stacked-layer structure of a plurality of oxide layers with different chemical compositions. For example, the atomic ratio of the element M to a metal element that is a main component of the metal oxide used as the oxide 230a is preferably greater than the atomic ratio of the element M to a metal element that is a main component of the metal oxide used as the oxide 230b. Moreover, the atomic ratio of the element M to In in the metal oxide used as the oxide 230a is preferably greater than the atomic ratio of the element M to In in the metal oxide used as the oxide 230b. With this structure, impurities and oxygen can be inhibited from diffusing into the metal oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 200 can have a high on-state current and high frequency characteristics.

When the oxide 230a and the oxide 230b contain a common element as the main component besides oxygen, the density of defect states at the interface between the oxide 230a and the oxide 230b can be reduced. Thus, the influence of interface scattering on carrier conduction is small, and the transistor 200 can have a high on-state current and excellent frequency characteristics.

Specifically, as the oxide 230a, a metal oxide with In:M:Zn=1:3:4 [atomic ratio] or a composition in the neighborhood thereof, or In:M:Zn=1:1:0.5 [atomic ratio] or a composition in the neighborhood thereof is used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is used. Note that a composition in the neighborhood includes the range of ±30% of an intended atomic ratio. Gallium is preferably used as the element M. In the case where a single layer of the oxide 230b is provided as the oxide 230, a metal oxide that can be used as the oxide 230a may be used as the oxide 2306b.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably has crystallinity. It is particularly preferable to use a CAAC-OS (C-Axis Aligned Crystalline Oxide Semiconductor) as the oxide 230b.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in a manufacturing process (what is called thermal budget).

If impurities and oxygen vacancies exist in a region of an oxide semiconductor where a channel is formed, a transistor using the oxide semiconductor may have variable electrical characteristics and poor reliability. In some cases, hydrogen in the vicinity of an oxygen vacancy forms a defect where hydrogen enters the oxygen vacancy (hereinafter, such defect is sometimes referred to as VoH), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and VoH are preferably reduced as much as possible in the region of the oxide semiconductor where a channel is formed. In other words, it is preferable that the region of the oxide semiconductor where a channel is formed have a reduced carrier concentration and be of an i-type (intrinsic) or substantially i-type.

As a countermeasure to the above, an insulator containing oxygen which is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH in the oxide semiconductor. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor is diffused into a conductor such as the gate electrode, the source electrode, or the drain electrode, the conductor might be oxidized and the conductivity might be impaired, for example, so that electrical characteristics and reliability of the transistor might be adversely affected.

Therefore, the region 230bc functioning as the channel formation region in the oxide semiconductor is preferably an i-type or substantially i-type region with reduced carrier concentration, whereas the region 230ba and the region 230bb functioning as the source region or the drain region are preferably n-type regions with high carrier concentrations. That is, the amounts of oxygen vacancies and VoH in the region 230bc of the oxide semiconductor are preferably reduced. Furthermore, it is preferable that the region 230ba and the region 230bb not be supplied with an excessive amount of oxygen and the amount of VOH in the region 230ba and the region 230bb not be excessively reduced. In addition, a reduction in conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form VoH; thus, the hydrogen concentration needs to be reduced in order to reduce the amount of VoH.

Thus, the semiconductor device of this embodiment has a structure in which the hydrogen concentration in the region 230bc is reduced, oxidation of the conductor 242a, the conductor 242b, and the conductor 260 is inhibited, and the hydrogen concentration in the region 230ba and the region 230bb is inhibited from being reduced.

In order to reduce the hydrogen concentration in the region 230bc, the insulator 253 preferably has a function of capturing hydrogen and fixing hydrogen. As illustrated in FIG. 3, the insulator 253 includes a region in contact with the region 230bc of the oxide 230b. With this structure, the hydrogen concentration in the region 230bc of the oxide 230b can be reduced. Accordingly, VoH in the region 230bc can be reduced, so that the region 230bc can be of an i-type or substantially i-type.

Examples of an insulator having a function of capturing hydrogen and fixing hydrogen include a metal oxide having an amorphous structure. For example, metal oxides such as magnesium oxide or oxide containing aluminum and/or hafnium can be given. In such a metal oxide having an amorphous structure, an oxygen atom has a dangling bond and sometimes has a property of capturing or fixing hydrogen with the dangling bond. That is, the metal oxide having an amorphous structure is highly capable of capturing hydrogen or fixing hydrogen.

In particular, for the insulator 253, an oxide containing aluminum and/or hafnium is preferably used, more preferably, an oxide containing aluminum and/or hafnium and having an amorphous structure is used, and further preferably, hafnium oxide having an amorphous structure is used. In this embodiment, hafnium oxide is used for the insulator 253. In this case, the insulator 253 contains at least oxygen and hafnium. The hafnium oxide has an amorphous structure. In this case, the insulator 253 has an amorphous structure.

Note that the insulator that can be used for the insulator 253 is not limited to the above-mentioned barrier insulator against hydrogen. An insulator having a thermally stable structure, such as silicon oxide or silicon oxynitride, can be used. For example, a stacked-layer film including an aluminum oxide film and a silicon oxide film or a silicon oxynitride film over the aluminum oxide film may be used as the insulator 253. Alternatively, for example, a stacked-layer film including an aluminum oxide film, a silicon oxide film or a silicon oxynitride film over the aluminum oxide film, and a hafnium oxide film over the silicon oxide film or the silicon oxynitride film may be used as the insulator 253.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also expressed to as having low permeability). In addition, a barrier property in this specification and the like means a function of capturing and fixing (also expressed as gettering) a targeted substance.

Examples of a barrier insulator against oxygen include oxide containing aluminum and/or hafnium, magnesium oxide, gallium oxide, indium gallium zinc oxide, silicon nitride, silicon nitride oxide and the like. As an oxide containing one or both of aluminum and hafnium, aluminum oxide, hafnium oxide, an oxide containing aluminum and hafnium (hafnium aluminate), an oxide containing hafnium and silicon (hafnium silicate), or the like can be given. For example, each of the insulator 253, the insulator 254, and the insulator 275 has a single-layer structure or a stacked-layer structure of the barrier insulator against oxygen.

The insulator 253 preferably has a barrier property against oxygen. Note that the insulator 253 is less permeable to oxygen than at least the insulator 280 is. The insulator 253 includes a region in contact with the side surface of the conductor 242a and the side surface of the conductor 242b. When the insulator 253 has a barrier property against oxygen, oxidation of the side surfaces of the conductor 242a and the conductor 242b, which forms oxide films on the side surfaces, can be inhibited. Accordingly, a reduction in on-state current or field-effect mobility of the transistor 200 can be inhibited.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the region 230bc of the oxide 230b caused by heat treatment or the like can be inhibited. This can inhibit formation of oxygen vacancies in the oxide 230a and the oxide 230b.

Even when an excess amount of oxygen is contained in the insulator 280, oxygen can be inhibited from being excessively supplied to the oxide 230a and the oxide 230b. Thus, the region 230ba and the region 230bb are inhibited from being excessively oxidized; a reduction in on-state current or field-effect mobility of the transistor 200 can be inhibited.

Oxide containing aluminum and/or hafnium has a barrier property against oxygen and thus can be suitably used for the insulator 253.

The insulator 254 preferably has a barrier property against oxygen. The insulator 254 is provided between the conductor 260 and the region 230bc of the oxide 230 and between the insulator 280 and the conductor 260. Such a structure can inhibit oxygen contained in the region 230bc of the oxide 230 from diffusing into the conductor 260 and thus can inhibit formation of oxygen vacancies in the region 230bc of the oxide 230. In addition, oxygen contained in the oxide 230 and oxygen contained in the insulator 280 can be inhibited from diffusing into the conductor 260 and oxidizing the conductor 260. Note that the insulator 254 is less permeable to oxygen than at least the insulator 280 is. For example, silicon nitride is preferably used for the insulator 254. In this case, the insulator 254 contains at least nitrogen and silicon.

The insulator 275 preferably has a barrier property against oxygen. The insulator 275 is provided between the insulator 280 and the conductor 242a and between the insulator 280 and the conductor 242b. The structure can inhibit diffusion of oxygen contained in the insulator 280 into the conductor 242a and the conductor 242b. Accordingly, oxidation of the conductor 242a and the conductor 242b by oxygen contained in the insulator 280 can be inhibited, so that an increase in resistivity and a reduction in on-state current of the transistor 200 can be inhibited. Note that the insulator 275 is less permeable to oxygen than at least the insulator 280 is. For example, silicon nitride is preferably used for the insulator 275. In this case, the insulator 275 contains at least nitrogen and silicon.

In order to inhibit a reduction in the hydrogen concentration in the region 230ba and the region 230bb, a barrier insulator against hydrogen is preferably provided in the vicinity of each of the region 230ba and the region 230bb. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 has a single-layer structure or a stacked-layer structure of the barrier insulator against hydrogen.

With the above structure, the region 230bc functioning as the channel formation region can be an i-type or substantially i-type region, the region 230ba and the region 230bb functioning as the source region and the drain region can be n-type regions, and thus a semiconductor device with favorable electrical characteristics can be provided. The semiconductor device with the above structure can have favorable electrical characteristics even when being miniaturized or highly integrated.

The insulator 253 functions as part of a gate insulator of the transistor 200. As illustrated in FIG. 1B, the insulator 253 is provided in contact with the side surface of the insulator 275 and the side surface of the insulator 280.

The insulator 253 needs to be provided in the opening formed in the insulator 280 and the like, together with the insulator 254 and the conductor 260. The thickness of the insulator 253 is preferably small for miniaturization of the transistor 200. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than 5.0 nm, and even further preferably greater than or equal to 1.0 nm and less than or equal to 3.0 nm. In this case, at least part of the insulator 253 preferably includes a region having the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Therefore, the insulator 253 can be deposited on, for example, the side surface of the opening formed in the insulator 280, a side edge portion of the conductor 242, and the like, with a small thickness like the above-described thickness and a favorable coverage.

Note that the thickness of the insulator 253 is not limited to the above. The thickness of the insulator 253 is set within a range of approximately 0.1 nm to 30 nm as appropriate, for example, when a case where the insulator 253 has a stacked-layer structure of an aluminum oxide film, a silicon oxide film over the aluminum oxide film, and a hafnium oxide film over the silicon oxide film or other cases are taken into consideration.

The insulator 254 functions as part of a gate insulator of the transistor 200. The insulator 254 preferably has a barrier property against hydrogen. This can prevent diffusion of impurities such as hydrogen contained in the conductor 260 into the oxide 230b.

Furthermore, the insulator 254 needs to be provided in an opening formed in the insulator 280 and the like, together with the insulator 253 and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 preferably includes a region having the above-described thickness.

For example, silicon nitride deposited by a PEALD method is used as the insulator 254

Note that when an insulator having a function of inhibiting the passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

The insulator 275 is provided to cover the insulator 222, insulator 224, the oxide 230a, the oxide 230b, and the conductor 242. The insulator 275 can have a structure including a region in contact with the top surface of the insulator 222, the top surface and the side surface of the conductor 242a, and the top surface and the side surface of the conductor 242b.

A conductive material that is less likely to be oxidized, a conductive material having a function of inhibiting diffusion of oxygen, or the like is preferably used for the conductor 242a, the conductor 242b, and the conductor 260. Examples of the conductive material include a conductive material containing nitrogen and a conductive material containing oxygen. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

One or both of the conductor 242 and the conductor 260 may have a stacked-layer structure. For example, as illustrated in FIG. 1B, the conductor 242a and the conductor 242b may each have a stacked-layer structure of two layers. In this case, for a layer (the conductor 242a1 and the conductor 242b1) in contact with the oxide 230b, a conductive material that is less likely to be oxidized, a conductive material having a function of inhibiting diffusion of oxygen, or the like is preferably used. For example, in the case where the conductor 260 has a stacked-layer structure of the conductor 260a and the conductor 260b as illustrated in FIG. 1B, a conductive material that is less likely to be oxidized, a conductive material having a function of inhibiting diffusion of oxygen, or the like is preferably used for the conductor 260a.

To inhibit a decrease in the conductivity of the conductor 242, an oxide having crystallinity, such as a CAAC-OS, is preferably used as the oxide 230b. As the oxide, a metal oxide that can be used as the oxide 230 described above is preferably used. Specifically, a metal oxide containing indium, zinc, and one or more selected from gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting oxygen from the metal oxide 230b. Furthermore, it is possible to inhibit a reduction in the conductivity of the conductor 242a and the conductor 242b.

With the above structure, a semiconductor device with a small variation in transistor characteristics can be provided. A semiconductor device with favorable frequency characteristics can be provided. A semiconductor device with high operating speed can be provided. A semiconductor device with favorable reliability can be provided. A semiconductor device having favorable electrical characteristics can be provided. A semiconductor device that can be miniaturized or highly integrated can be provided.

As illustrated in FIG. 1C, a curved surface may be provided between the side surface of the oxide 230b and the top surface of the oxide 230b in a cross-sectional view of the transistor 200 in the channel width direction. In other words, an end portion of the side surface and an end portion of the top surface may be curved (hereinafter, also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, and further preferably greater than or equal to 2 nm and less than or equal to 10 nm. Such a shape can improve the coverage of the oxide 230b with the insulator 253, the insulator 254, and the conductor 260.

As illustrated in FIG. 1C or the like, the insulator 253 is provided in contact with the top surface and the side surface of the oxide 230, whereby indium contained in the oxide 230 is unevenly distributed, in some cases, at the interface between the oxide 230 and the insulator 253 and in its vicinity. Accordingly, the vicinity of the surface of the oxide 230 has an atomic ratio close to that of an indium oxide or that of an In—Zn oxide. Such an increase in the atomic ratio of indium in the vicinity of the surface of the oxide 230, especially the vicinity of a surface of the oxide 230b, can increase the field-effect mobility of the transistor 200.

In addition to the above structure, the semiconductor device of this embodiment preferably has a structure in which hydrogen is inhibited from entering the transistor 200. For example, an insulator having a function of inhibiting diffusion of hydrogen is preferably provided to cover the transistor 200. In the semiconductor device described in this embodiment, the insulator corresponds to, for example, the insulator 212.

As the insulator 212, an insulator having a function of inhibiting diffusion of hydrogen is preferably used. This can inhibit diffusion of hydrogen into the transistor 200 from below the insulator 212. Note that an insulator that can be used as the insulator 275 described above is used the insulator 212.

At least one of the insulator 212, the insulator 214, and the insulator 282 preferably functions as a barrier insulating film that inhibits diffusion of impurities such as water and hydrogen from the substrate side or above the transistor 200 into the transistor 200. Thus, at least one of the insulator 212, the insulator 214, and the insulator 282 is preferably formed using an insulating material having a function of inhibiting diffusion of impurities (through which the impurities are unlikely to pass) such as a hydrogen atom, a hydrogen molecule, a water molecule, a nitrogen atom, a nitrogen molecule, a nitrogen oxide molecule (e.g., N₂O, NO, or NO₂), or a copper atom. Alternatively, at least one of the insulator 212, the insulator 214, and the insulator 282 is preferably formed using an insulating material having a function of inhibiting diffusion of oxygen (e.g., at least one of oxygen atoms, oxygen molecules, and the like) (an insulating material through which the above oxygen is less likely to pass).

An insulator having a function of inhibiting diffusion of oxygen and impurities such as water and hydrogen is preferably used as the insulator 212, the insulator 214, and the insulator 282; for example, aluminum oxide, magnesium oxide, hafnium oxide, gallium oxide, indium gallium zinc oxide, silicon nitride, or silicon nitride oxide can be used. For example, silicon nitride, which has a higher hydrogen barrier property, is preferably used for the insulator 212. For example, aluminum oxide, magnesium oxide, or the like, which has an excellent function of capturing and fixing hydrogen, is preferably used for the insulator 214 and the insulator 282. Accordingly, impurities such as water and hydrogen can be inhibited from diffusing from the substrate side to the transistor 200 side through the insulator 212 and the insulator 214. Alternatively, impurities such as water and hydrogen can be inhibited from diffusing to the transistor 200 side from an interlayer insulating film and the like which are provided outward from the insulator 282. Alternatively, oxygen contained in the insulator 224 and the like can be inhibited from diffusing to the substrate side through the insulator 212 and the insulator 214. Alternatively, oxygen contained in the insulator 280 and the like can be inhibited from diffusing into the components above the transistor 200 through the insulator 282 and the like. In this manner, the transistor 200 is preferably surrounded by the insulator 212, the insulator 214, and the insulator 282 which have a function of inhibiting diffusion of oxygen and impurities such as water and hydrogen.

Here, an oxide having an amorphous structure is preferably used as the insulator 212, the insulator 214, and the insulator 282. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as a component of the transistor 200 or provided around the transistor 200, hydrogen contained in the transistor 200 or hydrogen around the transistor 200 can be captured or fixed. In particular, hydrogen contained in the channel formation region of the transistor 200 is preferably captured or fixed. The metal oxide having an amorphous structure is used as a component of the transistor 200 or provided around the transistor 200, whereby the transistor 200 and a semiconductor device which have favorable characteristics and high reliability can be manufactured.

Although the insulator 212, the insulator 214, and the insulator 282 preferably have an amorphous structure, they may partly include a region with a polycrystalline structure. The insulator 212, the insulator 214, and the insulator 282 may have a multilayer structure in which a layer with an amorphous structure and a layer with a polycrystalline structure are stacked. For example, a stacked-layer structure in which a layer having a polycrystalline structure is formed over a layer having an amorphous structure may be employed.

The insulator 212, the insulator 214, and the insulator 282 can be formed by a sputtering method, for example. A deposition gas in a sputtering method need not include molecules containing hydrogen, and therefore the hydrogen concentration of the insulator 212, the insulator 214, and the insulator 282 can be reduced. Note that the deposition method is not limited to a sputtering method, and a chemical vapor deposition (CVD) method, a molecular beam epitaxy (MBE) method, a pulsed laser deposition (PLD) method, an ALD method, or the like can be used as appropriate.

The resistivity of the insulator 212 is preferably low in some cases. For example, by setting the resistivity of the insulator 212 to approximately 1×10¹³ Ωcm, the insulator 212 can sometimes reduce charge up of the conductor 205, the conductor 242, the conductor 260, or the conductor 240 in treatment using plasma or the like in the manufacturing process of a semiconductor device. The resistivity of the insulator 212 is preferably higher than or equal to 1×10¹⁰ Ωcm and lower than or equal to 1×10¹⁵ Ωcm.

The permittivitys of the insulator 216, the insulator 280, and the insulator 285 are preferably lower than that of the insulator 214. In the case where a material with a low permittivity is used for an interlayer film, the parasitic capacitance between wirings can be reduced. For the insulator 216, the insulator 280, and the insulator 285, for example, silicon oxide, silicon oxynitride, silicon oxide to which fluorine is added, silicon oxide to which carbon is added, silicon oxide to which carbon and nitrogen are added, porous silicon oxide, or the like is used as appropriate.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion formed in the conductor 205a. Here, the top surface of the conductor 205b is substantially level with top surfaces of the conductor 205a and the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from being diffused into the oxide 230 through the insulator 216, the insulator 224, and the like. When the conductor 205a is formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, the conductor 205a may be a single layer or a stacked layer of the above conductive materials. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 functions as a second gate electrode of the transistor 200 in some cases. In that case, by changing a potential applied to the conductor 205 out of synchronization with and independently of a potential applied to the conductor 260, the threshold voltage (Vth) of the transistor 200 can be controlled.

The electric resistivity of the conductor 205 is set in consideration of the potential applied to the conductor 205, and the thickness of the conductor 205 is determined in accordance with the electric resistivity. The thickness of the insulator 216 is substantially equal to the thickness of the conductor 205. The conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, which makes it possible to reduce the amount of the impurities to be diffused into the oxide 230.

As illustrated in FIG. 1A, the conductor 205 is preferably provided to be larger than a region of the oxide 230 that does not overlap with the conductor 242a or the conductor 242b. As illustrated in FIG. 1C, it is particularly preferable that the conductor 205 extend to a region outside end portions of the oxide 230a and the oxide 230b in the channel width direction. That is, the conductor 205 and the conductor 260 preferably overlap with each other with the insulators therebetween on the outer side of the side surface of the oxide 230 in the channel width direction. With this structure, the channel formation region in the oxide 230 can be electrically surrounded by the electric field of the conductor 260 functioning as a first gate electrode of the transistor 200 and the electric field of the conductor 205 functioning as the second gate electrode of the transistor 200. In this way, the transistor 200 can have an enhanced resistance to a short-channel effect, that is, the transistor 200 can be a transistor in which a short-channel effect is less likely to occur. In addition, the channel formation region that would be formed at the interface between the oxide 230 and the gate insulator or in the vicinity of the interface can be extended to the entire bulk of the oxide 230; thus, the density of current flowing through the transistor can be increased, so that an increase in the on-state current or the field-effect mobility of the transistor can be expected.

Note that the transistor structure that can be used in one embodiment of the present invention is not limited to that illustrated in FIG. 1. For example, a transistor structure that can be used in one embodiment of the present invention is one or more selected from a planar structure, a Fin-type structure, and the structure illustrated in FIG. 1.

Furthermore, as illustrated in FIG. 1C, the conductor 205 is extended to function as a wiring as well. However, without limitation to this, a structure in which a conductor functioning as a wiring is provided below the conductor 205 may be employed. In addition, the conductor 205 is not necessarily provided in each transistor. The conductor 205 may be shared by a plurality of transistors, for example.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 function as a gate insulator of the transistor 200.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. As the insulator, aluminum oxide, hafnium oxide, an oxide containing aluminum and hafnium (hafnium aluminate), or the like is preferably used. Alternatively, an oxide containing hafnium and zirconium, e.g., a hafnium-zirconium oxide is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of the insulator and any of silicon oxide, silicon oxynitride, or silicon nitride may be used for the insulator 222.

For example, a single layer or stacked layers of an insulator(s) containing what is called a high-k material such as aluminum oxide, hafnium oxide, tantalum oxide, zirconium oxide, or hafnium-zirconium oxide may be used for the insulator 222. As miniaturization and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr) TiO₃ (BST) may be used for the insulator 222.

Silicon oxide or silicon oxynitride, for example, can be used as appropriate for the insulator 224 that is in contact with the oxide 230.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a, as illustrated in FIG. 1B and the like. In this case, the insulator 275 is in contact with the side surfaces of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface and the side surface of the oxide 230b, the side surface of the oxide 230a, and the side surface of the insulator 224. Here, a structure can be employed in which the conductor 242a and the conductor 242b are in contact with the side surfaces of the insulator 224, the oxide 230a, and the oxide 230b in the channel length direction and are not in contact with the side surfaces of the insulator 224, the oxide 230a, and the oxide 230b in the channel width direction. Part of the conductor 242a and part of the conductor 242b are in contact with the top surface of the insulator 222. Part of the conductor 242a is in contact with the side surface of the insulator 222 and part of the insulator 216. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230b or the like is diffused into the conductor 242a or the conductor 242b in some cases. In particular, when a nitride containing tantalum is used for the conductor 242a and the conductor 242b, hydrogen contained in the oxide 230b or the like is likely to diffuse into the conductor 242a or the conductor 242b, and the hydrogen that has diffused is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242 in the channel width direction of the transistor 200. When no curved surface is formed in the conductor 242, the conductor 242 can have a large cross-sectional area in the channel width direction of the transistor 200 as illustrated in FIG. 1D. Accordingly, the resistance of the conductor 242 can be reduced, and the contact resistance between the transistor 200 and the capacitor 100 can be reduced.

As illustrated in FIG. 1A, the conductor 242a includes an opening in a region between the transistor 200a and the transistor 200b. The conductor 240 is placed to overlap with the opening. Note that in the top view of the transistor 200, the size of the opening is preferably smaller than the size of the conductor 240. With this structure, a region where the conductor 242a is in contact with the conductor 240 can be provided. Thus, the conductor 242a and the conductor 240 are electrically connected to each other.

Although the memory cell illustrated in FIG. 1A has a structure in which the conductor 242a of the transistor 200a and the conductor 242a of the transistor 200b are integrated, the present invention is not limited thereto. For example, the conductor 242a of the transistor 200a and the conductor 242a of the transistor 200b may be separated from each other. With such a structure, the width of the conductor 242 in the Y direction can be set to the minimum line width, so that the semiconductor device can be highly integrated. In the above case, part of the top surface and part of the side surface of the conductor 242a of the transistor 200a are in contact with the conductor 240, and part of the top surface and part of the side surface of the conductor 242a of the transistor 200b are in contact with the conductor 240. With such a structure, the conductor 240 functioning as the plug is electrically connected to the transistor 200a and the transistor 200b.

In the semiconductor device illustrated in FIG. 1A to FIG. 1D, the conductor 242 has a stacked-layer structure of two layers. Specifically, the conductor 242a includes the conductor 242a1 and the conductor 242a2 over the conductor 242a1. Similarly, the conductor 242b includes the conductor 242b1 and the conductor 242b2 over the conductor 242b1. At this time, the conductor 242a1 and the conductor 242b1 are placed so as to be in contact with the oxide 230b.

Although details will be described later, the conductor 242a1 and the conductor 242a2 can be formed using the same material in the same process as the conductor 242b1 and the conductor 242b2, respectively. Thus, the conductor 242a1 preferably includes the same conductive material as the conductor 242b1. The conductor 242a2 preferably includes the same conductive material as the conductor 242b2.

Hereinafter, the conductor 242a1 and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242a1 and the conductor 242b1) of the conductor 242 is preferably formed using a conductive material having a property of oxidation resistance. This can inhibit the oxidation of the lower layer of the conductor 242 and a reduction in the conductivity of the conductor 242. Note that the lower layer of the conductor 242 may have such a property that hydrogen is easily absorbed (easily extracted) thereinto. Accordingly, hydrogen in the oxide 230 is diffused into the lower layer of the conductor 242, so that the hydrogen concentration in the oxide 230 can be reduced. As a result, the transistor 200 can have stable electrical characteristics. The lower layer of the conductor 242 preferably has high compressive stress, and preferably has higher compressive stress than the upper layer of the conductor 242. Thus, the region 230ba and the region 230bb that are in contact with the lower layer of the conductor 242 can be stable n-type regions with a high carrier concentration.

The upper layer (the conductor 242a2 and the conductor 242b2) of the conductor 242 preferably has higher conductivity than that of the lower layer (the conductor 242a1 and the conductor 242b1) of the conductor 242. For example, the upper layer of the conductor 242 is thicker than the lower layer of the conductor 242. Note that at least part of the upper layer of the conductor 242 includes a region with higher conductivity than that of the lower layer of the conductor 242. Alternatively, the upper layer of the conductor 242 is preferably formed using a conductive material with lower resistivity than that of the lower layer of the conductor 242. As a result, a semiconductor device with reduced wiring delay can be fabricated.

Note that the upper layer of the conductor 242 may have such a property that hydrogen is easily absorbed. Accordingly, hydrogen absorbed by the lower layer of the conductor 242 is also diffused into the upper layer of the conductor 242, so that the hydrogen concentration in the oxide 230 can be further reduced. As a result, the transistor 200 can have stable electrical characteristics.

In the case where the conductor 242 has a stacked-layer structure of two layers, one or more selected from the constituent elements, chemical composition, and deposition conditions may be different between the lower layer of the conductor 242 and the upper layer of the conductor 242.

For example, tantalum nitride or titanium nitride can be used for the lower layer (the conductor 242a1 and the conductor 242b1) of the conductor 242, and tungsten can be used for the upper layer (the conductor 242a2 and the conductor 242b2) of the conductor 242. In this case, the conductor 242a1 and the conductor 242b1 are each a conductor containing tantalum or titanium and nitrogen. With this structure, it is possible to inhibit the oxidation of the lower layer of the conductor 242 and a reduction in the conductivity of the conductor 242. With this structure, the conductor 242a2 can be surrounded by the insulator 275 having a barrier property against oxygen and the conductor 242a1 having a property of being less likely to be oxidized, and the conductor 242b2 can be surrounded by the insulator 275 having a barrier property against oxygen and the conductor 242b1 having a property of being less likely to be oxidized. Thus, a semiconductor device in which oxidation of the conductor 242a2 and the conductor 242b2 and wiring delay are inhibited can be manufactured. In addition, when tungsten is used for the upper layer of the conductor 242, the conductor 242 can function as a wiring.

It is also possible to use a nitride containing tantalum (e.g., tantalum nitride) may be used for the lower layer of the conductor 242 and to use a nitride containing titanium (e.g., titanium nitride) may be used for the upper layer of the conductor 242, for example. Titanium nitride can have higher conductivity than tantalum nitride; thus, the conductivity of the upper layer of the conductor 242 can be higher than that of the lower layer of the conductor 242. Thus, the contact resistance between the conductor 242 and the conductor 240 provided in contact with the top surface of the conductor 242 can be reduced, so that a semiconductor device with reduced wiring delay can be manufactured.

Although the lower layer of the conductor 242 and the upper layer of the conductor 242 are formed using different conductive materials in the above-described example, the present invention is not limited thereto. For the lower layer of the conductor 242 and the upper layer of the conductor 242, conductive materials containing the same constituent elements and different chemical compositions may be used. In this case, the lower layer of the conductor 242 and the upper layer of the conductor 242 can be deposited successively without being exposed to an atmospheric environment. By the deposition without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum at an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, a nitride containing tantalum at an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. As a result, a semiconductor device with reduced wiring delay can be fabricated.

Note that the boundary between the upper layer and the lower layer of the conductor 242 is difficult to clearly detect in some cases. In the case where a nitride containing tantalum is used for the conductor 242, the tantalum concentration and the nitrogen concentration detected in each layer may gradually change within each layer and may also change continuously (or in a gradation manner) in a region between the upper layer and the lower layer. That is, the atomic ratio of nitrogen to tantalum is preferably higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

Although the transistor 200 having a structure in which the conductor 242 has a stacked-layer structure of two layers is illustrated, the present invention is not limited thereto. For example, the conductor 242 may have a single-layer structure or a stacked-layer structure of three or more layers. In the case where a component has a stacked-layer structure, layers may be distinguished by ordinal numbers given corresponding to the formation order.

The top surface of the conductor 260 is placed to be substantially level with the uppermost portion of the insulator 254, the uppermost portion of the insulator 253, and the top surface of the insulator 280.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. Although the conductor 260 has a two-layer structure of the conductor 260a and the conductor 260b in FIG. 1B and FIG. 1C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, for example, titanium, titanium nitride, tantalum, tantalum nitride, ruthenium, or ruthenium oxide is preferably used.

The conductor 260 is formed to fill the opening 258 extending in the channel width direction of the transistor 200, and the conductor 260 extends in the channel width direction as well. Thus, when the plurality of transistors 200 are provided, the conductor 260 can function as a wiring. In this case, the insulator 253 and the insulator 254 also extend together with the conductor 260.

The conductor 260 also functions as a wiring and thus is preferably formed using a conductor having high conductivity. For example, a conductive material containing tungsten, copper, or aluminum as its main component is preferably used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening 258 formed in the insulator 280 and the like. The formation of the conductor 260 in this manner allows the conductor 260 to be placed properly without alignment in a region between the conductor 242a and the conductor 242b.

As illustrated in FIG. 1C, in the channel width direction of the transistor 200, with reference to the bottom surface of the insulator 222, the level of the bottom surface of the conductor 260 in a region where the conductor 260 and the oxide 230b do not overlap with each other is preferably lower than the level of the bottom surface of the oxide 230b. When the conductor 260 functioning as the gate electrode of the transistor 200 covers the side surface and the top surface of the channel formation region of the oxide 230b with the insulator 253 and the like therebetween, the electric field of the conductor 260 is likely to affect the entire channel formation region in the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in a region where the conductor 260 does not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening 258 is formed in a region where the insulator 253, the insulator 254, and the conductor 260 are to be provided. In addition, the top surface of the insulator 280 may be planarized.

The insulator 280 functioning as an interlayer film preferably has a low permittivity. In the case where a material with a low permittivity is used for an interlayer film, the parasitic capacitance between wirings can be reduced. The insulator 280 is preferably provided using a material similar to that for the insulator 216, for example. In particular, silicon oxide and silicon oxynitride, which are thermally stable, are preferable. In particular, preferred materials are silicon oxide, silicon oxynitride, and porous silicon oxide with which a region containing oxygen to be released by heating can be easily formed.

The concentration of impurities such as water and hydrogen in the insulator 280 is preferably reduced. Oxide containing silicon such as silicon oxide, silicon oxynitride, or the like is used as appropriate for the insulator 280, for example.

The insulator 282 is provided to be in contact with at least parts of the top surfaces of the conductor 260, the insulator 253, the insulator 254, and the insulator 280.

The insulator 282 preferably functions as a barrier insulating film that inhibits impurities such as water and hydrogen from being diffused into the insulator 280 from above and preferably has a function of capturing impurities such as hydrogen. The insulator 282 preferably functions as a barrier insulating film that inhibits passage of oxygen. For the insulator 282, a metal oxide having an amorphous structure, for example, an insulator such as aluminum oxide is used. In this case, the insulator 282 contains at least oxygen and aluminum. When the insulator 282 having a function of capturing impurities such as hydrogen is provided in contact with the insulator 280, impurities such as hydrogen contained in the insulator 280 and the like can be captured. It is preferable to use, in particular, aluminum oxide having an amorphous structure for the insulator 282, because hydrogen can be captured or fixed more effectively in some cases. Accordingly, the transistor 200 and a semiconductor device which have favorable characteristics and high reliability can be manufactured.

As the insulator 282, aluminum oxide is preferably deposited by a sputtering method, further preferably, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 is smaller as the RF power is lower, and the amount of oxygen is easily saturated even when the insulator 282 has a small thickness. Moreover, the amount of oxygen implanted into the layer below the insulator 282 is larger as the RF power is higher.

The RF power is higher than or equal to 0 W/cm² and lower than or equal to 1.86 W/cm², for example. In other words, an appropriate amount of oxygen for the characteristics of the transistor 200 can be changed and implanted by RF power used for the formation of the insulator 282. Accordingly, an appropriate amount of oxygen for improving the reliability of the transistor 200 can be implanted. Note that an RF power of 0 W/cm² means that RF power is not applied to the substrate.

The RF frequency is preferably greater than or equal to 10 MHz. The typical frequency is 13.56 MHz. The higher the RF frequency is, the less damage the substrate gets.

Although FIG. 1A to FIG. 1D and the like illustrate a single-layer structure of the insulator 282, the present invention is not limited to this structure, and a stacked-layer structure of two or more layers may be employed. The insulator 282 may have a two-layer structure, for example.

An upper layer and a lower layer of the insulator 282 are preferably formed using the same material by different methods. For example, when aluminum oxide is deposited as the insulator 282 by a pulsed DC sputtering method with use of an aluminum target in an atmosphere containing an oxygen gas, RF power applied to the substrate in the deposition of the lower layer of the insulator 282 and RF power applied to the substrate in the deposition of the lower layer of the insulator 282 are preferably different from each other, and the RF power applied to the substrate in the deposition of the lower layer of the insulator 282 is preferably lower than the RF power applied to the substrate in the deposition of the lower layer of the insulator 282. With this structure, the insulator 282 can have an amorphous structure, and the amount of oxygen supplied to the insulator 280 can be controlled.

Note that the RF power applied to the substrate in the deposition of the lower layer of the insulator 282 may be higher than the RF power applied to the substrate in the deposition of the upper layer of the insulator 282. With this structure, the amount of oxygen supplied to the insulator 280 can be increased.

The thickness of the lower layer of the insulator 282 is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With such a structure, the lower layer of the insulator 282 can have an amorphous structure regardless of the RF power. When the lower layer of the insulator 282 has an amorphous structure, the upper layer of the insulator 282 easily has an amorphous structure, so that the insulator 282 as a whole can have an amorphous structure.

Although the lower layer of the insulator 282 and the upper layer of the insulator 282 described above form a stacked-layer structure of the same material, the present invention is not limited thereto. The lower layer of the insulator 282 and the upper layer of the insulator 282 may be stacked layers containing different materials.

The above is the description of the transistor 200.

### Capacitor 100

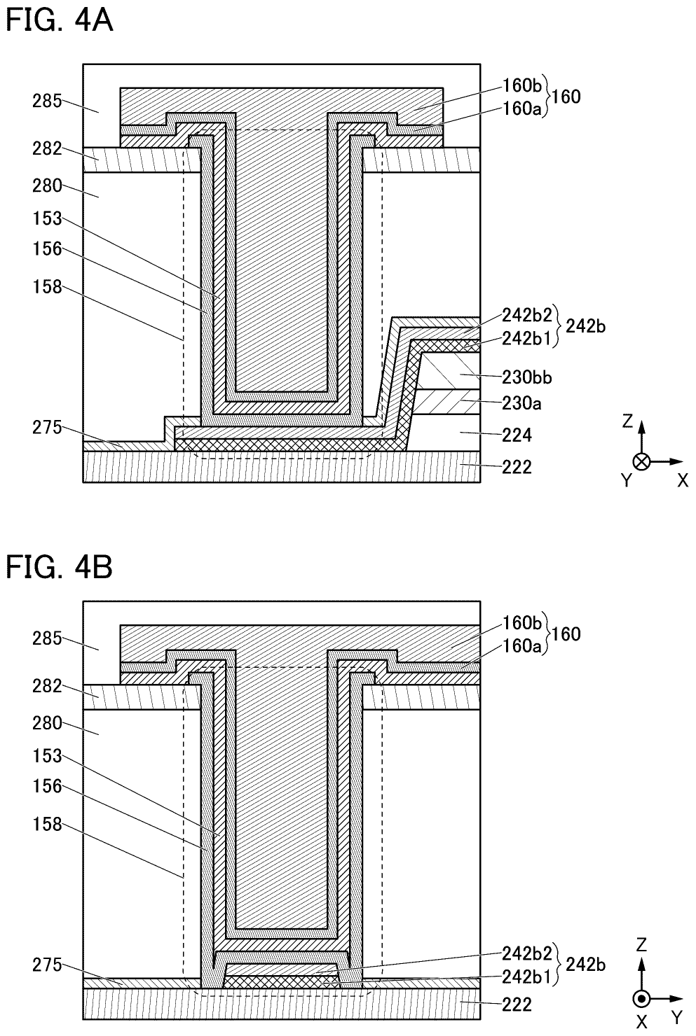

FIG. 4A is an enlarged view of the capacitor 100 and the vicinity thereof in FIG. 1B, and FIG. 4B is an enlarged view of the capacitor 100 and the vicinity thereof in FIG. 1D.

The capacitor 100 includes the conductor 156, the insulator 153, and the conductor 160 (a conductor 160a and a conductor 160b). The conductor 156 functions as one of a pair of electrodes of the capacitor 100 (also referred to as a lower electrode), the conductor 160 functions as the other of the pair of electrodes of the capacitor 100 (also referred to as an upper electrode), and the insulator 153 functions as the dielectric of the capacitor 100.

At least parts of the conductor 156, the insulator 153, the conductor 160a, and the conductor 160b are placed in the opening 158 provided in the insulator 275, the insulator 280, and the insulator 282. The conductor 156 is provided over the conductor 242b, the insulator 153 is provided over the conductor 156, the conductor 160a is provided over the insulator 153, and the conductor 160b is provided over the conductor 160a.

The conductor 156 is placed along the opening 158 formed in the insulator 275, the insulator 280, and the insulator 282. The level of part of the top surface of the conductor 156 is preferably higher than the level of the top surface of the insulator 282. The top surface of the conductor 242b is in contact with the bottom surface of the conductor 156. The conductor 156 is preferably deposited by a deposition method with good coverage, such as an ALD method or a CVD method, and a conductor that can be used as the conductor 205, the conductor 260, or the conductor 242 may be used. When the same conductive material as the conductor 242b is used for the conductor 156, for example, the contact resistance between the conductor 156 and the conductor 242b can be reduced. Titanium nitride or tantalum nitride deposited by an ALD method can be used for the conductor 156, for example.

The insulator 153 is placed to cover the conductor 156 and part of the insulator 282. For the capacitor 100 to function as a ferroelectric capacitor, a material that can have ferroelectricity is preferably used for the insulator 153.

As the material that can have ferroelectricity, for example, hafnium oxide is preferably used. Other examples of the material that can have ferroelectricity include metal oxides such as zirconium oxide and HfZrO_{X} (X is a real number greater than 0). Alternatively, as the material that can have ferroelectricity, a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide can be used.

Here, the atomic ratio of a hafnium atom to the element J1 can be set as appropriate. For example, the atomic ratio of a hafnium atom to a zirconium atom may be 1:1 or in the neighborhood thereof. Alternatively, as the material that can have ferroelectricity, a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide, or the like can be used. The atomic ratio of zirconium to the element J2 can be set as appropriate; the atomic ratio of zirconium to the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may also be used.

As the material that can have ferroelectricity, scandium aluminum nitride (Al₁₋ₐScₐN_{b} (a is a real number greater than 0 and less than 0.5, and b is 1 or an approximate value thereof), hereinafter simply referred to as AlScN), an Al—Ga—Sc nitride, a Ga—Sc nitride, or the like can be used. As the material that can have ferroelectricity, a metal nitride containing an element M1, an element M2, and nitrogen can also be used. Here, the element M1 is one or more selected from aluminum (Al), gallium (Ga), indium (In), and the like. The element M2 is one or more selected from boron (B), scandium (Sc), yttrium (Y), lanthanoids (lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)), actinoids (15 elements from actinium (Ac) to lawrencium (Lr)), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen shows ferroelectricity in some cases even though the metal oxide does not contain the element M2. As the material that can have ferroelectricity, a material in which an element M3 is added to the above metal nitride can be used. Note that the element M3 is one or more selected from magnesium (Mg), calcium (Ca), strontium (Sr), zinc (Zn), cadmium (Cd), and the like. Here, the atomic ratio of the element M1 to the element M2 and the element M3 can be set as appropriate. Since the above metal nitride contains at least a Group 13 element and nitrogen, which is a Group 15 element, the metal nitride is referred to as a ferroelectric belonging to Group 13 to Group 15, a ferroelectric of a Group 13 nitride, or the like in some cases.

As the material that can have ferroelectricity, a perovskite-type oxynitride such as SrTaO₂N or BaTaO₂N, GaFeO₃ with a κ-alumina-type structure, or the like can be used.

The material that can have ferroelectricity can be, for example, a mixture or a compound formed of a plurality of materials selected from the above-listed materials. Alternatively, the material that can have ferroelectricity can have a stacked-layer structure of a plurality of materials selected from the above-listed materials. Since the above-listed materials may change their crystal structures or characteristics according to a variety of processes and the like as well as deposition conditions, a material that exhibits ferroelectricity is referred to not only as a ferroelectric but also as a material that can have ferroelectricity or a material that has ferroelectricity in this specification and the like.

Among the materials that can have ferroelectricity, a material containing hafnium oxide or hafnium oxide and zirconium oxide (typically, HfZrOₓ) is suitable because the material can have ferroelectricity even when being processed into a thin film of several nanometers.

Alternatively, scandium aluminum nitride (AlScN), which can be formed by a sputtering method, is suitable for the material that can have ferroelectricity because the impurity concentration in the film can be reduced or a dense film can be formed. In the case where scandium aluminum nitride (AlScN) is used as the material that can have ferroelectricity, a film can be expected to have high reliability.

The thickness of the material that can have ferroelectricity can be less than or equal to 100 nm, preferably less than or equal to 50 nm, further preferably less than or equal to 20 nm, still further preferably less than or equal to 10 nm (typically, greater than or equal to 2 nm and less than or equal to 9 nm). The thickness is preferably greater than or equal to 8 nm and less than or equal to 12 nm, for example. When the material that can have ferroelectricity has a thickness in the above range, ferroelectricity can be exhibited with a thin film. When thinned, the ferroelectric layer can be interposed between a pair of electrodes of a capacitor, and the capacitor can be combined with a semiconductor element such as a miniaturized transistor to fabricate a semiconductor device. That is, a semiconductor device that occupies a small area can be easily obtained.

Note that in this specification and the like, the material that can have ferroelectricity is referred to as a ferroelectric material in some cases. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is referred to as a ferroelectric device in this specification and the like, in some cases.

In the case where HfZrOx is used as the material that can have ferroelectricity, an ALD method, specifically, a thermal ALD method is preferably used for deposition. In the case where deposition of the material that can have ferroelectricity is performed by a thermal ALD method, it is suitable to use a material that does not contain a hydrocarbon (also referred to as Hydro Carbon or HC) for a precursor. When the material that can have ferroelectricity contains one or both of hydrogen and carbon, crystallization of the material that can have ferroelectricity might be hindered. Thus, the precursor that does not contain a hydrocarbon is preferably used as described above to reduce the concentration(s) of one or both of hydrogen and carbon in the material that can have ferroelectricity. Examples of the precursor that does not contain a hydrocarbon include a chlorine-based material. In the case where a material containing hafnium oxide and zirconium oxide (HfZrOₓ) is used as the material that can have ferroelectricity, HfCl₄ and/or ZrCl₄ are/is used as the precursor. On the other hand, a dopant (typically, silicon, carbon, or the like) for controlling the polarization state may be added to the material that can have ferroelectricity. In that case, a formation method using a material containing hydrocarbon as a precursor may be used as a way of adding carbon as a dopant.

In the case where a film of the material that can have ferroelectricity is deposited, impurities in the film, at least one or more of hydrogen, a hydrocarbon, and carbon here, are thoroughly removed, whereby a highly purified intrinsic film having ferroelectricity can be formed. Note that the highly purified intrinsic film having ferroelectricity and a highly purified intrinsic oxide semiconductor are highly compatible with each other in the manufacturing process. Thus, a method for manufacturing a semiconductor device with high productivity can be provided.

The material that can have ferroelectricity preferably has a low impurity concentration. In particular, the concentrations of hydrogen (H) and carbon (C) are preferably as low as possible. Specifically, the hydrogen concentration of the material that can have ferroelectricity is preferably lower than or equal to 5×10²⁰ atoms/cm³, further preferably lower than or equal to 1×10²⁰ atoms/cm³. The carbon concentration of the material that can have ferroelectricity is preferably lower than or equal to 5×10¹⁹ atoms/cm³, further preferably lower than or equal to 1×10¹⁹ atoms/cm³.

In the case where HfZrO_{X} is used as the material that can have ferroelectricity, it is preferable to deposit hafnium oxide and zirconium oxide alternately by an ALD method such that the ratio of hafnium oxide to zirconium oxide is 1:1.

In the case where deposition of the material that can have ferroelectricity is performed by an ALD method, H₂O or O₃ can be used as an oxidizer. However, the oxidizer in the ALD method is not limited thereto. For example, the oxidizer in the ALD method may contain any one or more selected from O₂, O₃, N₂O, NO₂, H₂O, and H₂O₂.

It is particularly preferable that the material that can have ferroelectricity have an orthorhombic crystal structure, in which case ferroelectricity appears. Note that another crystal structure may be included in addition to the orthorhombic crystal structure. For example, in addition to the orthorhombic crystal structure, any one or more crystal structures selected from a cubic crystal structure, a tetragonal crystal structure, an orthorhombic crystal structure, and a monoclinic crystal structure may be included. Note that a layer for improving the crystallinity may be formed before forming the material that can have ferroelectricity. For example, in the case where HfZrOₓ is used as the material that can have ferroelectricity, a metal oxide such as hafnium oxide or zirconium oxide, hafnium, or zirconium can be used for the layer for improving the crystallinity.

In the case where AlScN is used as the material that can have ferroelectricity, the material preferably has a hexagonal crystal structure. Note that another crystal structure may be included in addition to the hexagonal crystal structure. For the layer for improving the crystallinity, a metal nitride such as aluminum nitride or scandium nitride, aluminum, or scandium is preferably used.

Note that the layer for improving the crystallinity may be formed after formation of the material that can have ferroelectricity. Alternatively, the material that can have ferroelectricity may have a composite structure of an amorphous structure and a crystal structure.

The conductor 160 is placed to fill the opening 158 formed in the insulator 275, the insulator 280, and the insulator 282. The conductor 160 is preferably deposited by an ALD method, a CVD method, or the like and a conductor that can be used as the conductor 205 or the conductor 260 may be used. For example, titanium nitride deposited by an ALD method can be used for the conductor 160a and tungsten deposited by a CVD method can be used for the conductor 160b. Note that in the case where the adhesion of tungsten to the insulator 153 is sufficiently high, a single-layer film of tungsten deposited by a CVD method may be used as the conductor 160.

The opening 158 is provided to reach the conductor 242b. That is, it can be said that the opening 158 includes a region overlapping with the conductor 242b. The conductor 242b is the other of the source electrode and the drain electrode of the transistor 200, and when the conductor 242b is in contact with the bottom surface of the conductor 156 provided in the opening 158, the transistor 200 and the capacitor 100 can be electrically connected to each other.

In a plan view, the distance between the opening 158 and the oxide 230 is preferably short. Such a structure can reduce the area occupied by a memory cell including the capacitor 100 and the transistor 200. Note that, in a plane view, the shape of the opening 158 may be a tetragonal shape, a polygonal shape other than a tetragonal shape, a polygonal shape with rounded corners, or a circular shape including an elliptical shape.

As illustrated in FIG. 4A and FIG. 4B, the conductor 156 is provided in contact with the bottom surface and the inner wall of the opening 158. Thus, the conductor 156 is in contact with the side surfaces of the insulator 275, the insulator 280, and the insulator 282, the side surface of the conductor 242b1, the side surface and the top surface of the conductor 242b2, and the top surface of the insulator 222. The insulator 153 is provided in contact with the top surface of the conductor 156, the conductor 160a is provided in contact with the top surface of the insulator 153, and the conductor 160b is provided in contact with the top surface of the conductor 160a.

When the capacitor 100 has the above structure, the capacitor 100 in which the conductor 156 and the conductor 160 face each other with the insulator 153 therebetween at the bottom surface and the side surface of the opening 158 can be formed, as illustrated in FIG. 4A and FIG. 4B. Thus, increasing the depth of the opening 158 (which can also be referred to as the thickness of the insulator 280) can increase the capacitance of the capacitor 100. Increasing the capacitance per unit area of the capacitor 100 in this manner enables read operation of the storage device to be stabilized.

As illustrated in FIG. 4A, part of the conductor 156, part of the insulator 153, and part of the conductor 160 are provided to be exposed out from the opening 158. In other words, part of the conductor 156, part of the insulator 153, and part of the conductor 160 are formed above the top surface of the conductor 260 or above the top surface of the insulator 282.

Part of the conductor 156 and part of the insulator 153 are in contact with the top surface of the insulator 282. That is, a side end portion of the conductor 156 is covered with the insulator 153. In addition, the conductor 160 preferably has a region overlapping with the insulator 282 with the insulator 153 therebetween. Here, as illustrated in FIG. 4A, a side end portion of the conductor 160 and a side end portion of the insulator 153 are substantially aligned with each other. With such a structure, the conductor 160 and the conductor 156 can be separated from each other by the insulator 153; thus, a short circuit between the conductor 160 and the conductor 156 can be inhibited.

Furthermore, a portion above the insulator 282 of the conductor 160 may be extended and formed as a wiring. For example, as illustrated in FIG. 1D, the conductor 160 can be provided to extend in the channel width direction of the transistor 200. Thus, when the plurality of transistors 200 and capacitors 100 are provided, the conductor 160 can function as a wiring. In that case, the insulator 153 as well as the conductor 160 can be provided in the extending manner.

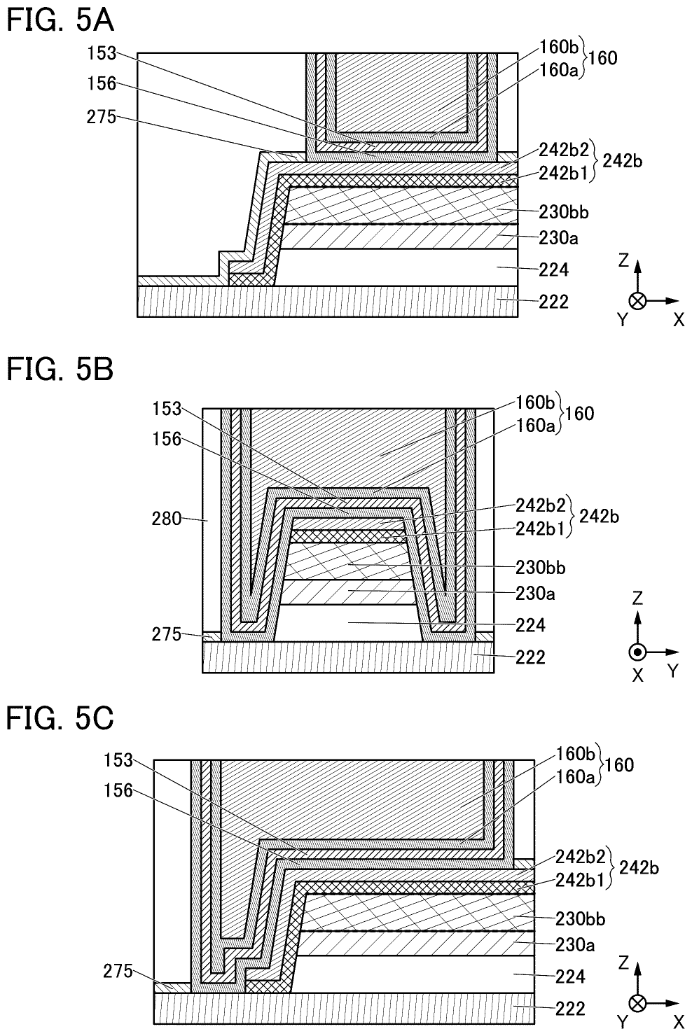

The capacitor 100 may have the structure illustrated in FIG. 5A and FIG. 5B. Here, FIG. 5A is an enlarged view corresponding to the capacitor 100 in FIG. 1B, and FIG. 5B is an enlarged view corresponding to the capacitor 100 in FIG. 1D.

In the capacitor 100, as illustrated in FIG. 5A, the insulator 224, the oxide 230a, and the oxide 230b (the region 230bb) may be formed under the conductor 242b in the opening 158. In that case, as illustrated in FIG. 5B, the conductor 156 is preferably provided in contact with the side surface of the insulator 224, the side surface of the oxide 230a, the side surface of the oxide 230b (the region 230bb), and the side surface of the conductor 242 (the conductor 242b). In this way, the capacitor 100 is formed along the side surface of the insulator 224, the side surface of the oxide 230a, the side surface of the oxide 230b (the region 230bb), and the side surface of the conductor 242 (the conductor 242b); thus, the capacitance of the capacitor 100 can be larger than that in the structure illustrated in FIG. 4 in some cases.

Alternatively, the capacitor 100 may have the shape illustrated in FIG. 5C, for example. Specifically, in part of the opening 158, the conductor 242b overlaps with the opening 158 as in the structure illustrated in FIG. 1B, and in the other part of the opening 158, the conductor 242b, the oxide 230b (the region 230bb), the oxide 230a, and the insulator 224 overlap with the opening 158 as in the structure illustrated in FIG. 5A.

Note that although FIG. 4A to FIG. 5C illustrate a structure in which the sidewall of the opening 158 is substantially perpendicular to the top surface of the insulator 222, the present invention is not limited thereto. The sidewall of the opening 158 may have a tapered shape. When the sidewall of the opening 158 has a tapered shape, the coverage with the insulator 153 and the like can be improved in a later step, so that defects such as a void can be reduced.

The above is the description of the capacitor 100.

The conductor 240 is provided in contact with the inner wall of the opening 206 formed in the insulator 285, the insulator 282, the insulator 280, the insulator 275, the conductor 242a, the insulator 216, and the insulator 212. The conductor 240 includes a region in contact with the top surface of the conductor 209. Note that the conductor 242a can be regarded as being placed such that part thereof protrudes into the opening 206.

The conductor 240 functions as a plug or a wiring for electrically connecting the transistor 200 to a circuit element such as a switch, a transistor, a capacitor, an inductor, a resistor, and a diode, a wiring, an electrode, or a terminal.

The conductor 240 preferably has a stacked-layer structure of the conductor 240a and the conductor 240b. For example, as illustrated in FIG. 1B, the conductor 240 can have a structure in which the conductor 240a is provided in contact with the inner wall of the opening and the conductor 240b is provided on the inner side. That is, the conductor 240a is positioned closer to the insulator 285, the insulator 282, the insulator 280, the insulator 275, the conductor 242a, the insulator 216, and the insulator 212, than the conductor 240b is.

Here, the conductor 240a is preferably formed by a film formation method with good coverage, such as an ALD method. When the conductor 240a is formed in this manner, the outline of the conductor 240a becomes substantially the same as the shape formed by the inner wall of the opening 206.

For the conductor 240a, a conductive material having a function of inhibiting passage of an impurity such as water or hydrogen is preferably. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. When the above material is used for the conductor 240a, impurities such as water and hydrogen contained in a layer above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component is preferably used for the conductor 240b.

For example, it is preferable to use titanium nitride for the conductor 240a and tungsten for the conductor 240b. In that case, the conductor 240a serves as a conductor containing titanium and nitrogen, and the conductor 240b serves as a conductor containing tungsten.

Although the conductor 240 in FIG. 1B and the like has a structure where the conductor 240a and the conductor 240b are stacked, the present invention is not limited to this structure. For example, the conductor 240 may have a single-layer structure or a stacked-layer structure of three or more layers. In the case where a component has a stacked-layer structure, layers may be distinguished by ordinal numbers given corresponding to the formation order.

The conductor 209 functions as part of a circuit element such as a switch, a transistor, a capacitor, an inductor, a resistor, or a diode, a wiring, an electrode, or a terminal.

The insulator 210 functions as an interlayer film. As the insulator 210, an insulator that can be used as the insulator 214, the insulator 216, or the like described above is used.

### Materials for Semiconductor Device

Component materials that can be used for the semiconductor device will be described below.

### Substrate

As a substrate over which the transistor 200 is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material, or a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor, a switching element, a light-emitting element, and a storage element.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. By contrast, when a material with a low relative permittivity is used for the insulator functioning as an interlayer film, parasitic capacitance generated between wirings can be reduced. Thus, a material is preferably selected depending on the function of an insulator.

Examples of the insulator having a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting the passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen released by heating is in contact with the oxide 230, oxygen vacancies included in the oxide 230 can be filled.

For the insulator functioning as the dielectric of the capacitor, any of the above-described materials that can have ferroelectricity can be used.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### Metal Oxide

The oxide 230 is preferably formed using a metal oxide functioning as a semiconductor (an oxide semiconductor). A metal oxide that can be used as the oxide 230 of the present invention will be described below.

The metal oxide preferably contains at least indium or zinc. In particular, indium and zinc are preferably contained. In addition to them, aluminum, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, an element M, and zinc is considered. Note that the element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (also referred to as IAGZO or IGAZO) may be used for the semiconductor layer.

Note that in this specification and the like, a metal oxide containing nitrogen is also collectively referred to as a metal oxide in some cases. A metal oxide containing nitrogen may be called a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

A semiconductor material that can be used for the oxide 230 is not limited to the above metal oxides. A semiconductor material that has a band gap (a semiconductor material that is not a zero-gap semiconductor) may be used for the oxide 230. For example, a single element semiconductor such as silicon, a compound semiconductor such as gallium arsenide, or a layered material functioning as a semiconductor (also referred to as an atomic layer material or a two-dimensional material) is preferably used as a semiconductor material. In particular, a layered substance functioning as a semiconductor is suitably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For the oxide 230, a transition metal chalcogenide functioning as a semiconductor is preferably used, for example. Specific examples of the transition metal chalcogenide which can be used for the oxide 230 include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). When the above transition metal chalcogenide is used for the oxide 230, a semiconductor device with a high on-state current can be provided.

### Modification Example of Semiconductor Device

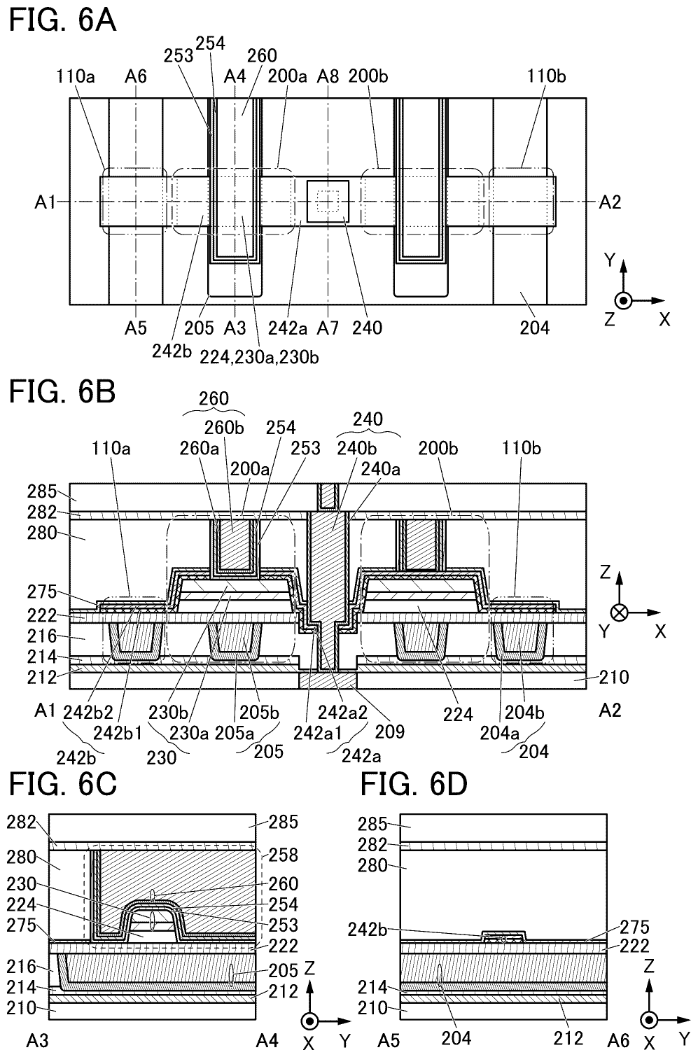

An example of the semiconductor device of one embodiment of the present invention will be described below with reference to FIG. 6.

FIG. 6A is a top view of the semiconductor device. FIG. 6B is a cross-sectional view corresponding to a portion indicated by the dashed-dotted line A1-A2 in FIG. 6A. FIG. 6C is a cross-sectional view corresponding to a portion indicated by dashed-dotted line A3-A4 in FIG. 6A. FIG. 6D is a cross-sectional view corresponding to a portion indicated by dashed-dotted line A5-A6 in FIG. 6A. Note that for clarity of the drawing, some components are not illustrated in the top view of FIG. 6A.

Note that in the semiconductor device illustrated in FIG. 6, components having the same functions as the components in the semiconductor device described in <Structure example of semiconductor device> are denoted by the same reference numerals. Note that the materials described in detail in <Structure example of semiconductor device> can also be used as component materials of the semiconductor device illustrated in FIG. 6.

The semiconductor device illustrated in FIG. 6A to FIG. 6D is different from the semiconductor device illustrated in FIG. 1A to FIG. 1D in the structure of the capacitor.

The semiconductor device illustrated in FIG. 6A to FIG. 6D includes a capacitor 110 (a capacitor 110a and a capacitor 110b) instead of the capacitor 100 included in the semiconductor device illustrated in FIG. 1A to FIG. 1D.

In the capacitor 110, a conductor 204 (a conductor 204a and a conductor 204b) functions as a lower electrode, the insulator 222 functions as a dielectric, and a conductor 242b (the conductor 242b1 and the conductor 242b2) functions as an upper electrode.

The insulator 222 is also an insulator functioning as part of the second gate insulator of the transistor 200. In order for the capacitor 110 to function as a ferroelectric capacitor, any of the above-described materials that can have ferroelectricity is preferably used for the insulator 222.

The conductor 204 can be formed using the same material and the same method as the conductor 205 functioning as the second gate electrode of the transistor 200. That is, the conductor 204a can be formed using the same material and the same method as the conductor 205a, and the conductor 204b can be formed using the same material and the same method as the conductor 205b.

In the semiconductor device illustrated in FIG. 6A to FIG. 6D, the insulator 222 can have both a function of the second gate insulator of the transistor 200 and a function of the dielectric of the capacitor 110. The conductor 204 functioning as the lower electrode of the capacitor 110 can be formed using the same material and the same method as the conductor 205 functioning as the second gate electrode of the transistor 200. Thus, the semiconductor device illustrated in FIG. 6A to FIG. 6D can be manufactured with a smaller number of steps than the semiconductor device illustrated in FIG. 1A to FIG. 1D.

According to one embodiment of the present invention, a novel transistor can be provided. A semiconductor device that can be reduced in size or highly integrated can be provided. A semiconductor device with favorable frequency characteristics can be provided. A semiconductor device with high operating speed can be provided. A semiconductor device with a small variation in transistor characteristics can be provided. A semiconductor device with favorable electrical characteristics can be provided. A semiconductor device with high reliability can be provided. A semiconductor device with a high on-state current can be provided. A semiconductor device with a high field-effect mobility can be provided. A semiconductor device with low power consumption can be provided.

The semiconductor device including the transistor 200 and the capacitor 100 described in this embodiment can be used as a memory cell of a storage device. The transistor 200 is a transistor in which a channel is formed in a semiconductor layer including an oxide semiconductor (an OS transistor). The transistor 200 has high frequency characteristics, and thus enables the storage device to perform read and write at high speed.

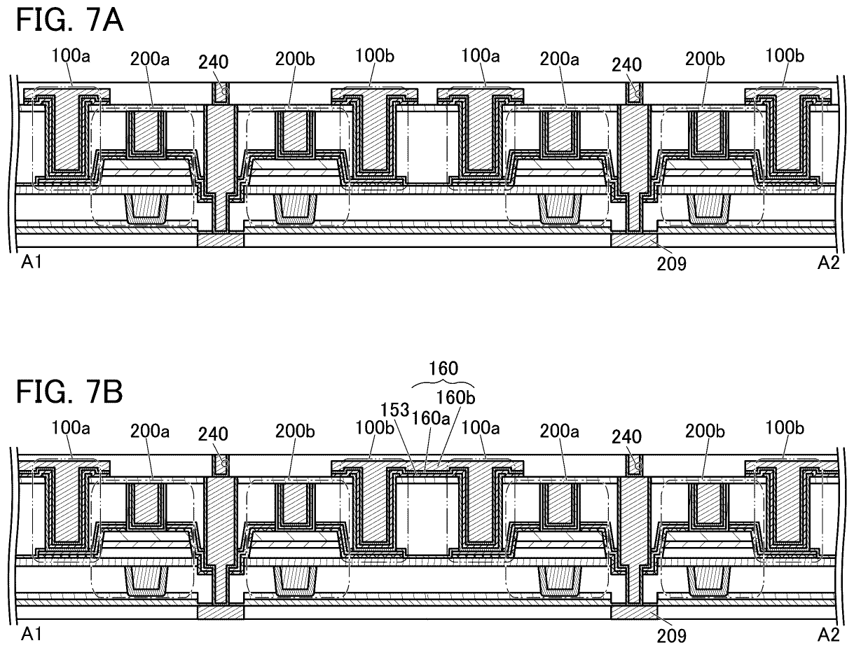

In the case where the semiconductor device including the transistor 200 and the capacitor 100 is used as a memory cell as described above, a memory cell array can be formed by arranging the memory cells in a matrix. As an example of the memory cell array, FIG. 7A illustrates an example in which a plurality of the memory cells are arranged in the A1-A2 direction.

Although FIG. 7A illustrates a structure in which the conductor 160 of the capacitor 100a and the conductor 160 of the capacitor 100b, which are adjacent each other, are separated from each other, the present invention is not limited thereto. For example, as illustrated in FIG. 7B, a structure may be employed in which the conductor 160 of the capacitor 100a and the conductor 160 of the capacitor 100b, which are adjacent each other, are integrated. At this time, the insulator 153 of the capacitor 100a and the insulator 153 of the capacitor 100b, which are adjacent to each other, may be integrated.

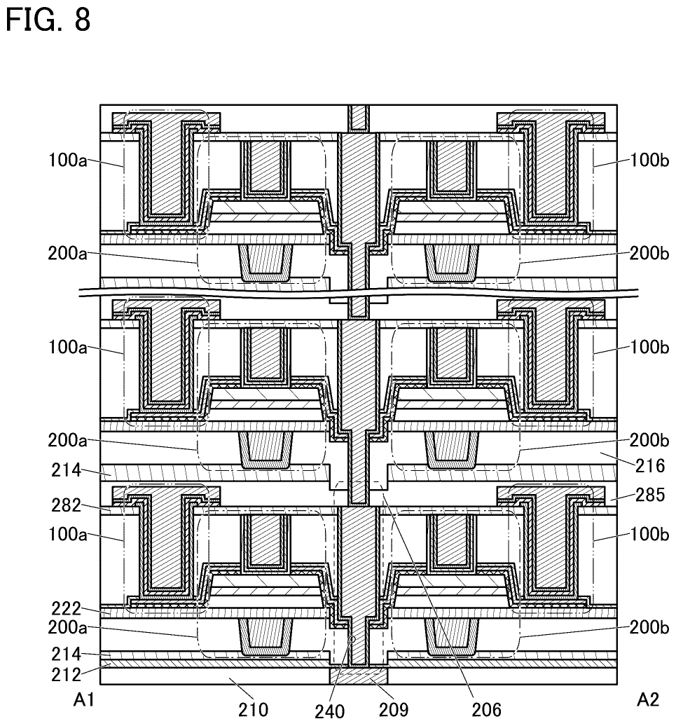

Alternatively, the memory cells may be stacked instead of being arranged on the same plane. FIG. 8 is a cross-sectional view of a structure in which a plurality of layers each including the above memory cell are stacked. In this case, it can be said that the storage device includes a plurality of layers each including a memory cell with the transistor 200 and the capacitor 100, and that a plurality of the layers are stacked. Alternatively, it can be said that the storage device includes a plurality of layers each including at least two memory cells, and that a plurality of the layers are stacked. Here, the memory cell including the transistor 200a and the capacitor 100a is referred to as a first memory cell, and a memory cell including the transistor 200b and the capacitor 100b is referred to as a second memory cell, in some cases.

Note that in the structure in FIG. 8, the insulator 212 is provided in the layer including the memory cell and being in contact with the insulator 210 and the conductor 209, but the insulator 212 is not provided in layers thereabove. However, without limitation to this structure, the insulator 212 may be provided in each layer that includes the memory cell.

Although FIG. 8 illustrates a structure in which a plurality of layers each including the memory cell are stacked, one embodiment of the present invention is not limited thereto. A plurality of layers each including the memory cell array illustrated in FIG. 7A or FIG. 7B may be stacked, for example. In this case, it can be said that the storage device includes a plurality of layers each including the memory cell array where memory cells with the transistor 200 and the capacitor 100 are provided, and that a plurality of the layers are stacked.

As illustrated in FIG. 8, each of the plurality of layers included in the storage device includes the opening 206. Specifically, each of the plurality of layers included in the storage device includes the opening 206 between the first memory cell and the second memory cell. More specifically, each of the plurality of layers included in the storage device includes the opening 206 between the transistor 200a and the transistor 200b. In addition, the openings 206 included in the plurality of layers include overlapping regions.

In this manner, the area occupied by the opening 206 can be reduced and the area occupied by one memory cell can be reduced, so that the storage capacity per area of the storage device can be increased.

The conductor 240 is placed in the opening 206 included in each of the plurality of layers. The conductors 240 included in the plurality of layers are provided to overlap with each other. Thus, the conductor 240 included in each of the plurality of layers is electrically connected to the transistor 200a and the transistor 200b included in each of the plurality of layers. Note that in this embodiment, the conductor 242a is shared by the transistor 200a and the transistor 200b. Thus, it can be said that the conductor 240 included in each of the plurality of layers is electrically connected to the conductor 242a included in each of the plurality of layers.

Although not illustrated in the drawing, an insulator is preferably provided over the conductor 240 in the uppermost layer of the plurality of layers. As this insulator, an insulator that can be used as the insulator 285, the insulator 282, or the like can be used, for example.

When a plurality of memory cells are stacked as illustrated in FIG. 8, cells can be integrally placed without increasing the area occupied by the memory cell array. In other words, a 3D memory cell array can be formed.

### Operation Example of Semiconductor Device

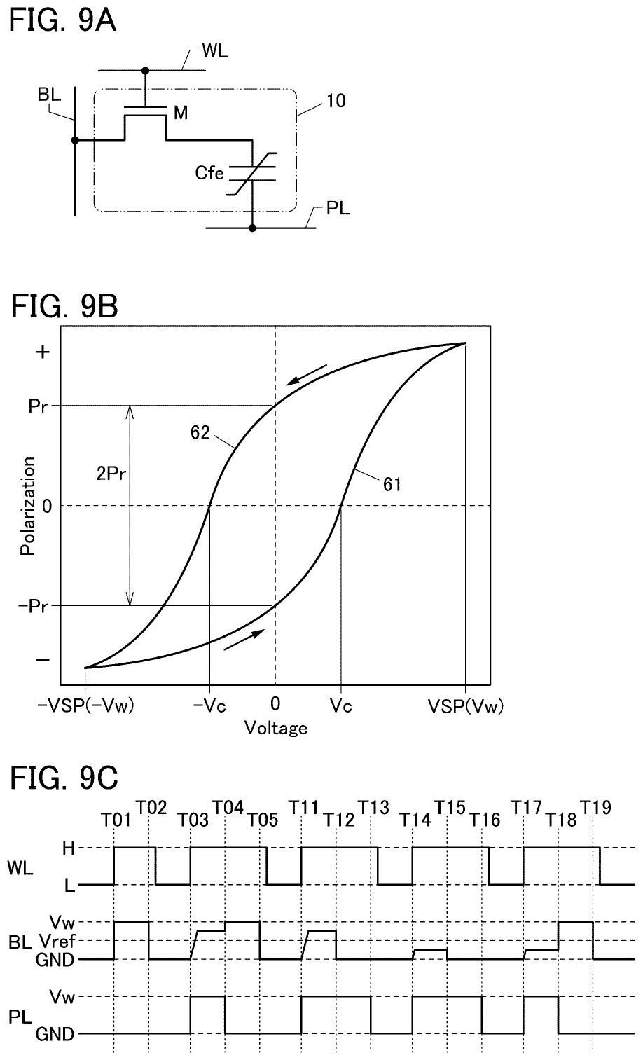

Next, an operation example of the semiconductor device of one embodiment of the present invention will be described. FIG. 9A shows an equivalent circuit diagram of the semiconductor device of one embodiment of the present invention. The semiconductor device illustrated in FIG. 9A is a DRAM (1Tr1C-type) storage element (memory cell) including one transistor M and one capacitor Cfe.

The capacitor Cfe includes a material that can have ferroelectricity as a ferroelectric layer between two electrodes. Thus, the semiconductor device of one embodiment of the present invention functions as a FeRAM (Ferroelectric Random Access Memory). The transistor M illustrated in FIG. 9A corresponds to the transistor 200, and the capacitor Cfe corresponds to the capacitor 100.

A variety of semiconductor materials can be used for a semiconductor layer in which the channel of the transistor M is formed. For example, as the semiconductor layer in which the channel of the transistor M is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, oxide semiconductor, or nitride semiconductor may be used.

In particular, an OS transistor is preferably used as the transistor M. The OS transistor has a characteristic of a high withstand voltage between its source and drain. Thus, with use of an OS transistor as the transistor M, a high voltage can be applied to the transistor M even when the transistor M is miniaturized. The miniaturization of the transistor M can reduce the area occupied by the semiconductor device. For example, the area occupied by one semiconductor device illustrated in FIG. 9A can be ⅓ to ⅙ of the area occupied by one cell of an SRAM. Accordingly, the semiconductor devices can be arranged at high density. Thus, a storage device having high storage capacity can be achieved.

In the case where an OS transistor is used as a transistor included in the memory cell, the memory cell can be referred to as an “OS memory”. In particular, the DRAM OS memory is referred to as a DOSRAM (registered trademark) in some cases. In addition, an FeRAM using an OS transistor as a transistor included in a memory cell is referred to as an FeDOSRAM in some cases.

The wiring WL has a function of a word line, and the potential of the wiring WL is controlled so that ON/OFF states of the transistor M can be controlled. For example, in the case where the transistor M is an n-channel transistor, the potential of the wiring WL is set to a high potential so that the transistor M can be turned on, while the potential of the wiring WL is set to a low potential so that the transistor M can be turned off.

The wiring BL has a function of a bit line, and a potential corresponding to the potential of the wiring BL is supplied to one electrode of the capacitor Cfe when the transistor M is in an on state.

The wiring PL functions as a plate line. A potential is supplied to the other electrode of the capacitor Cfe through the wiring PL.

### Hysteresis Characteristics

A ferroelectric layer included in the capacitor Cfe has hysteresis characteristics. FIG. 9B is a graph showing an example of the hysteresis characteristics. The horizontal axis in FIG. 9B represents the voltage applied to the ferroelectric layer. The voltage can be a difference between the potential of one electrode of the capacitor Cfe and the potential of the other electrode of the capacitor Cfe, for example.

In addition, in FIG. 9B, the vertical axis represents polarization of the ferroelectric layer; a positive value indicates that positive charges are concentrated on one electrode side of the capacitor Cfe and negative charges are concentrated on the other electrode side of the capacitor Cfe. On the other hand, a negative value of the polarization indicates that positive charges are concentrated on the other electrode side of the capacitor Cfe and negative charges are concentrated on the one electrode side of the capacitor Cfe.

Note that the voltage represented by the horizontal axis of the graph in FIG. 9B may be a difference between the potential of the other electrode of the capacitor Cfe and the potential of the one electrode of the capacitor Cfe. Furthermore, the polarization represented by the vertical axis of the graph in FIG. 9B may be a positive value in the case where positive charges are concentrated on the other electrode side of the capacitor Cfe and negative charges are concentrated on the one electrode side of the capacitor Cfe, and may be a negative value in the case where positive charges are concentrated on the one electrode side of the capacitor Cfe and negative charges are concentrated on the other electrode side of the capacitor Cfe.

As shown in FIG. 9B, the hysteresis characteristics of the ferroelectric layer can be represented by a curve 61 and a curve 62. The voltages at the intersecting points between the curve 61 and the curve 62 are VSP and −VSP. The polarities of VSP and −VSP can be said to be different.

A voltage lower than or equal to −VSP is applied to the ferroelectric layer, and the voltage applied to the ferroelectric layer is increased, in which case the polarization of the ferroelectric layer is increased along the curve 61. On the other hand, a voltage higher than or equal to VSP is applied to the ferroelectric layer, and then the voltage applied to the ferroelectric layer is decreased, in which case the polarization of the ferroelectric layer is decreased along the curve 62. Thus, VSP and −VSP can each be referred to as a saturation polarization voltage. Incidentally, VSP is referred to as a first saturation polarization voltage and −VSP is referred to as a second saturation polarization voltage in some cases. In addition, the absolute values of the first saturation polarization voltage and the second saturation polarization voltage are equal to each other in FIG. 9B, but may be different from each other.

Here, Vc represents a voltage applied to the ferroelectric layer in the case where the polarization of the ferroelectric layer is 0 in the change of the polarization of the ferroelectric layer along the curve 61. In addition, −Vc represents a voltage applied to the ferroelectric layer in the case where the polarization of the ferroelectric layer is 0 in the change of the polarization of the ferroelectric layer along the curve 62. Vc and −Vc can each be referred to as coercive voltage. The value of Vc and the value of −Vc can be said to be values between −VSP and VSP. For example, Vc is referred to as a first coercive voltage and −Vc is referred to as a second coercive voltage in some cases. Note that the absolute values of the first coercive voltage and the second coercive voltage are equal to each other in FIG. 9B, but may be different from each other.

The maximum value and the minimum value of polarization when a voltage is not applied to the ferroelectric layer are referred to as “remanent polarization Pr” and “remanent polarization −Pr”, respectively. A difference between the remanent polarization Pr and the remanent polarization −Pr is referred to as “remanent polarization 2Pr”.

As described above, a voltage applied to the ferroelectric layer included in the capacitor Cfe can be expressed by a difference between the potential of one electrode of the capacitor Cfe and the potential of the other electrode of the capacitor Cfe. As described above, the other electrode of the capacitor Cfe is electrically connected to the wiring PL. Thus, by controlling the potential of the wiring PL, the voltage applied to the ferroelectric layer included in the capacitor Cfe can be controlled.

An example of a method of driving the semiconductor device functioning as a memory cell is described. In the following description, the voltage applied to the ferroelectric layer of the capacitor Cfe indicates a difference (potential difference) between the potential of one electrode of the capacitor Cfe and the potential of the other electrode of the capacitor Cfe (the wiring PL). In addition, the transistor M is an n-channel transistor.

FIG. 9C is a timing chart showing an example of a driving method of the semiconductor device. FIG. 9C illustrates an example of writing and reading 2-bit digital data in and out of the semiconductor device. Specifically, in FIG. 9C, data “1” is written in the semiconductor device from Time T01 to Time T02; the data “1” is read out and rewritten from Time T03 to Time T05; the data “1” is read out, and data “0” is written in the semiconductor device from Time T11 to Time T13; the data “0”0 is read out and rewritten from Time T14 to Time T16; and the data “0” is read out and data “1” is written in the semiconductor device from Time T17 to Time T19.

A sense amplifier electrically connected to the wiring BL is supplied with Vref as a reference potential. In the readout operation illustrated in FIG. 9C or the like, when the potential of the wiring BL is higher than Vref, data “1” is read out by a bit line driver circuit. In contrast, when the potential of the wiring BL is lower than Vref, data “0” is read out by the bit line driver circuit.

From Time T01 to Time T02, the potential of the wiring WL is set to a high potential. Thus, the transistor M is turned on. In addition, the potential of the wiring BL is set to Vw. Since the transistor M is in an on state, the potential of one electrode of the capacitor Cfe becomes Vw. In addition, the potential of the wiring PL is set to GND. Accordingly, the voltage applied to the ferroelectric layer of the capacitor Cfe becomes “Vw−GND”. As a result, (the) data “1” can be written in the semiconductor device. Consequently, the period from Time T01 to Time T02 can be referred to as a write operation period.

Here, Vw is preferably higher than or equal to VSP, and is preferably equal to VSP, for example. In this specification and the like, GND can be set to a ground potential, but is not necessarily a ground potential as long as the semiconductor device can be driven so as to achieve an object of one embodiment of the present invention. For example, when the absolute value of the first saturation polarization voltage is different from the absolute value of the second saturation polarization voltage, and the absolute value of the first coercive voltage is different from the absolute value of the second coercive voltage, GND can be a potential other than a ground.

From Time T02 to Time T03, the potential of the wiring BL and the potential of the wiring PL are set to GND. Accordingly, the voltage applied to the ferroelectric layer of the capacitor Cfe becomes 0 V. The voltage “Vw−GND” applied to the ferroelectric layer of the capacitor Cfe from Time T01 to Time T02 can be higher than or equal to VSP, and thus the polarization quantity of the ferroelectric layer of the capacitor Cfe is changed along the curve 62 in FIG. 9B from Time T02 to Time T03. From the above, from Time T02 to Time T03, polarization inversion does not occur in the ferroelectric layer of the capacitor Cfe.

After the potential of the wiring BL and the potential of the wiring PL are set to GND, the potential of the wiring WL is set to a low potential. Thus, the transistor M is turned off. Through the above steps, the write operation is completed and data “1” is held in the semiconductor device. Note that the potentials of the wiring BL and the wiring PL can be any potentials as long as polarization inversion does not occur in the ferroelectric layer of the capacitor Cfe, i.e., the voltage applied to the ferroelectric layer of the capacitor Cfe is higher than or equal to −Vc as the second coercive voltage.

From Time T03 to Time T04, the potential of the wiring WL is set to a high potential. Thus, the transistor M is turned on. The potential of the wiring PL is set to Vw. By setting the potential of the wiring PL to Vw, the voltage applied to the ferroelectric layer of the capacitor Cfe becomes “GND−Vw”. As described above, from Time T01 to Time T02, the voltage applied to the ferroelectric layer of the capacitor Cfe is “Vw−GND”. Thus, polarization inversion occurs in the ferroelectric layer of the capacitor Cfe. At the time of the polarization inversion, a current flows through the wiring BL, and the potential of the wiring BL becomes higher than Vref. Thus, the bit line driver circuit can read out the data “1” held in the semiconductor device. Accordingly, the period from Time T03 to Time T04 can be referred to as a readout operation period. Note that Vref is higher than GND and lower than Vw but may be higher than Vw, for example.

Since the above readout is destructive readout, the data “1” held in the semiconductor device is lost. Thus, from Time T04 to Time T05, the potential of the wiring BL is set to Vw and the potential of the wiring PL is set to GND. Thus, data “1” is rewritten in the semiconductor device. Consequently, the period from Time T04 to Time T05 can be referred to as a rewrite operation period.

From Time T05 to Time T11, the potential of the wiring BL and the potential of the wiring PL are set to GND. After that, the potential of the wiring WL is set to a low potential. Through the above steps, the rewrite operation is completed, and the data “1” is held in the semiconductor device.

From Time T11 to Time T12, the potential of the wiring WL is set to a high potential and the potential of the wiring PL is set to Vw. Since the data “1” is held in the semiconductor device, the potential of the wiring BL becomes higher than Vref and the data “1” held in the semiconductor device is read out. Accordingly, the period from Time T11 to Time T12 can be referred to as a readout operation period.

From Time T12 to Time T13, the potential of the wiring BL is set to GND. Since the transistor M is in an on state, the potential of one electrode of the capacitor Cfe becomes GND. The potential of the wiring PL is set to Vw. In the above manner, the voltage applied to the ferroelectric layer of the capacitor Cfe becomes to be “GND−Vw”. As a result, data “0” can be written in the semiconductor device. Consequently, the period from Time T12 to Time T13 can be referred to as a write operation period.

From Time T13 to Time T14, the potential of the wiring BL and the potential of the wiring PL are set to GND. Accordingly, the voltage applied to the ferroelectric layer of the capacitor Cfe becomes 0 V. The voltage “GND−Vw” applied to the ferroelectric layer of the capacitor Cfe from Time T12 to Time T13 can be set to be −VSP or lower; thus, the polarization quantity of the ferroelectric layer of the capacitor Cfe is changed along the curve 61 in FIG. 9B from Time T13 to Time T14. From the above, from Time T13 to Time T14, polarization inversion does not occur in the ferroelectric layer of the capacitor Cfe.

After the potential of the wiring BL and the potential of the wiring PL are set to GND, the potential of the wiring WL is set to a low potential. Thus, the transistor M is turned off. Through the above steps, the write operation is completed and data “0” is held in the semiconductor device. Note that the potentials of the wiring BL and the wiring PL can be any potentials as long as polarization inversion does not occur in the ferroelectric layer of the capacitor Cfe, i.e., the voltage applied to the ferroelectric layer of the capacitor Cfe is lower than or equal to Vc as the first coercive voltage.

From Time T14 to Time T15, the potential of the wiring WL is set to a high potential. Thus, the transistor M is turned on. The potential of the wiring PL is set to Vw. By setting the potential of the wiring PL to Vw, the voltage applied to the ferroelectric layer of the capacitor Cfe becomes “GND−Vw”. As described above, the voltage applied to the capacitor layer of the capacitor Cfe from Time T12 to Time T13 is “GND−Vw”. Thus, polarization inversion does not occur in the ferroelectric layer of the capacitor Cfe. Consequently, the amount of current flowing through the wiring BL is smaller than that in the case where the polarization inversion occurs in the ferroelectric layer of the capacitor Cfe. Accordingly, the increase amount in the potential of the wiring BL is smaller than that in the case where the polarization inversion occurs in the ferroelectric layer of the capacitor Cfe; specifically, the potential of the wiring BL becomes lower than or equal to Vref. Thus, the bit line driver circuit can read out the data “0” held in the semiconductor device. Accordingly, the period from Time T14 to Time T15 can be referred to as a readout operation period.

From Time T15 to Time T16, the potential of the wiring BL is set to GND and the potential of the wiring PL is set to Vw. Thus, data “0” is rewritten in the semiconductor device. Accordingly, the period from Time T15 to Time T16 can be referred to as a rewrite operation period.

From Time T16 to Time T17, the potential of the wiring BL and the potential of the wiring PL are set to GND. After that, the potential of the wiring WL is set to a low potential. Through the above steps, the rewrite operation is completed, and the data “0” is held in the semiconductor device.

From Time T17 to Time T18, the potential of the wiring WL is set to a high potential and the potential of the wiring PL is set to Vw. Since the data “0” is held in the semiconductor device, the potential of the wiring BL becomes lower than Vref and the data “0” held in the semiconductor device is read out. Accordingly, the period from Time T17 to Time T18 can be referred to as a readout operation period.

The potential of the wiring BL is set to Vw from Time T18 to Time T19. Since the transistor M is in an on state, the potential of one electrode of the capacitor Cfe becomes Vw. The potential of the wiring PL is set to GND. Accordingly, the voltage applied to the ferroelectric layer of the capacitor Cfe becomes “Vw−GND”. As a result, data “1” can be written in the semiconductor device. Consequently, the period from Time T18 to Time T19 can be referred to as a write operation period.

After Time T19, the potential of the wiring BL and the potential of the wiring PL are set to GND. After that, the potential of the wiring WL is set to a low potential. Through the above steps, the write operation is completed and the data “1” is held in the semiconductor device.

The semiconductor device including the ferroelectric layer in the capacitor Cfe functions as a nonvolatile storage element that can hold information written therein even when power supply is stopped.

A DRAM requires regular refresh operation and thus increases power consumption. The semiconductor device that includes the capacitor Cfe including a ferroelectric layer does not require refresh operation and thus can have low power consumption.

In this specification and the like, a storage element including a ferroelectric layer or a memory circuit including a ferroelectric layer is referred to as a “ferroelectric memory” or an “FE memory” in some cases. Thus, the semiconductor device of one embodiment of the present invention is a ferroelectric memory and is also an FE memory. The FE memory can be expected to achieve the number of rewrite cycles of 1×10¹⁰ or more, preferably 1×10¹² or more, further preferably 1×10¹⁵ or more. The FE memory can be expected to achieve an operation frequency of greater than or equal to 10 MHz, preferably greater than or equal to 1 GHz.

In the FE memory, the remanent polarization 2Pr and data holding capability have a correlation, and as the remanent polarization 2Pr becomes smaller, the data holding capability declines. In this specification and the like, a period over which the remanent polarization 2Pr is reduced by 5% (the data holding capability declines by 5%) is referred to as a “memory holding period”. The FE memory can be expected to have a memory holding period of ten days or longer, preferably one year or longer, further preferably ten years or longer at a temperature environment of 150° C. or 200° C.

The FE memory can also be applied to a cache memory and a register in a CPU (Central Processing Unit), a GPU (Graphics Processing Unit), and the like. An Noff-CPU (Normally off CPU) can be obtained by a combination of the FE memory with a cache memory and a register in a CPU. An Noff-GPU (Normally off GPU) can be obtained by a combination of the FE memory with a cache memory and a register in a GPU.

The storage device including the memory cell array will be described in detail in a later embodiment.

At least part of the structure, method, and the like described in this embodiment can be implemented in appropriate combination with any of the other embodiments described in this specification.

### Embodiment 2

In this embodiment, a structure example of a storage device using the semiconductor device described in the above embodiment as a memory cell will be described.

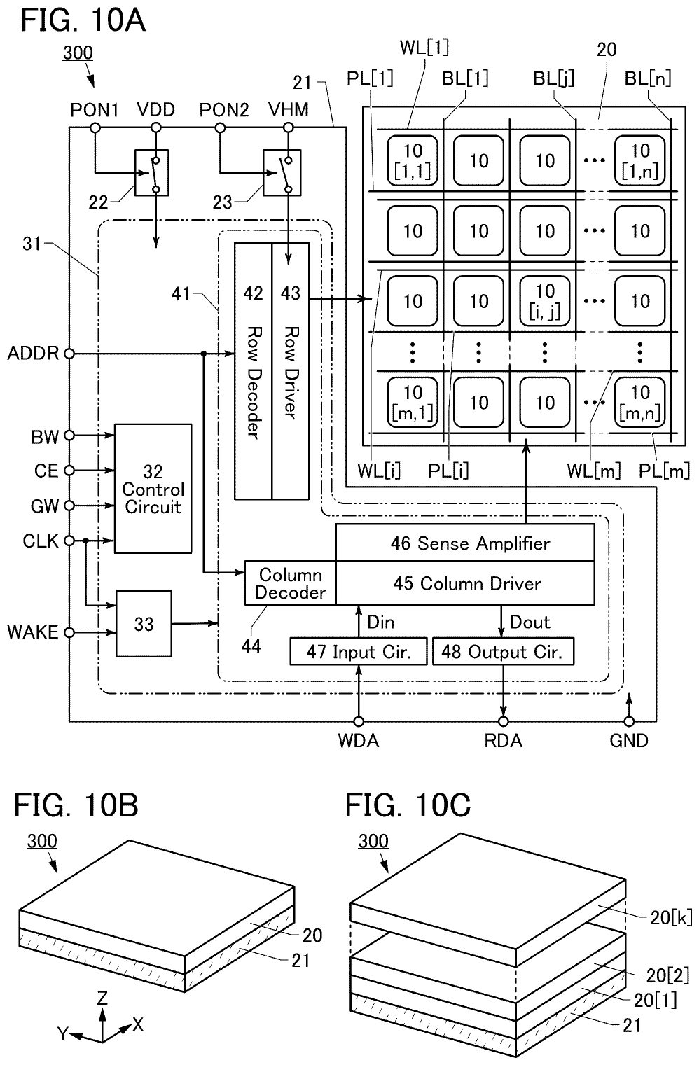

FIG. 10A is a block diagram illustrating a structure example of the storage device 300 of one embodiment of the present invention. The storage device 300 illustrated in FIG. 10A includes a driver circuit 21 and a memory array 20. The memory array 20 includes a plurality of memory cells 10. FIG. 10A illustrates an example in which the memory array 20 includes the plurality of memory cells 10 arranged in a matrix of m rows and n columns (each of m and n is an integer greater than or equal to 2).

Note that the rows and the columns extend in directions orthogonal to each other. In this embodiment, the X direction (direction along the X-axis) is referred to as a “row” and the Y direction (direction along the Y-axis) is referred to as a “column”, but the X direction may be referred to as a “column” and the Y direction may be referred to as a “row”.

In FIG. 10A, the memory cell 10 in the first row and the first column is denoted as a memory cell 10[1, 1] and a memory cell 10 in the m-th row and the n-th column is denoted as a memory cell 10[m, n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is denoted as a memory cell 10[i, j]. Note that in this embodiment and the like, “i+a” (a is a positive or negative integer) is not below 1 and does not exceed m. Similarly, “j +a” is not below 1 and does not exceed n.

The memory array 20 includes m wirings WL extending in the row direction, m wirings PL extending in the row direction, and n wirings BL extending in the column direction. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n].

The plurality of memory cells 10 provided in the i-th row are electrically connected to the wiring WL in the i-th row (wiring WL[i]) and the wiring PL in the i-th row (wiring PL[i]). The plurality of memory cells 10 provided in the j-th column are electrically connected to the wiring BL in the j-th column (wiring BL[j]).

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 10A but can be more than one. In this case, a power switch is provided for each power domain.

The driver circuit 21 and the memory array 20 may be provided on the same plane. As illustrated in FIG. 10B, a layer including the memory array 20 may be provided directly over a layer including the driver circuit 21. When the driver circuit 21 and the memory array 20 are provided to overlap with each other, the signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the storage device 300 can be downsized.

In FIG. 10B, the memory array 20 is provided as one layer over the driver circuit 21 to overlap with the driver circuit 21; however, two or more layers of the memory arrays 20 may be provided over the driver circuit 21 to overlap with the driver circuit 21. FIG. 10C illustrates an example in which k layers (k is an integer greater than or equal to 2) of the memory arrays 20 are provided over the driver circuit 21 to overlap with the driver circuit 21. In FIG. 10C and the like, the memory array 20 in the first layer is denoted as a memory array 20[1], the memory array 20 in the second layer is denoted as a memory array 20[2], and the memory array 20 in the k-th layer is denoted as a memory array 20[k].

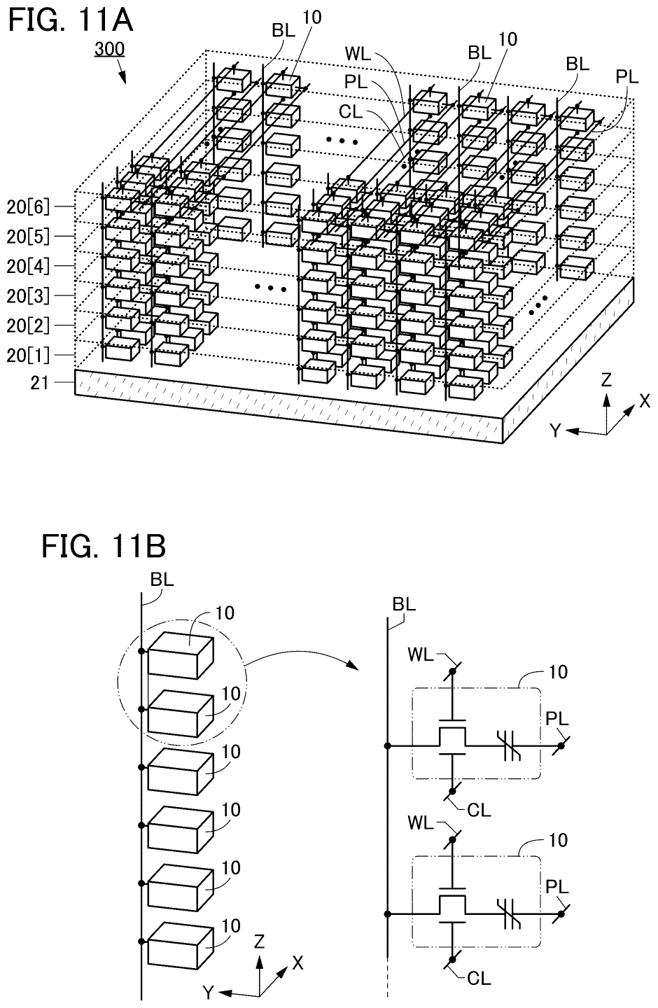

FIG. 11A is a schematic diagram illustrating a structure example of the storage device 300. The storage device 300 illustrated in FIG. 11A includes six layers of the memory arrays 20 provided over the driver circuit 21. As described above, in FIG. 11A and the like, the memory array 20 provided in the third layer is denoted as a memory array 20[3], the memory array 20 provided in the fourth layer is denoted as a memory array 20[4], the memory array 20 provided in the fifth layer is denoted as a memory array 20[5], and the memory array 20 provided in the sixth layer is denoted as a memory array 20 [6].

Each layer of the memory arrays 20 includes a plurality of memory cells 10 arranged in a matrix, and the wiring WL, the wiring CL, and the wiring PL extending in the X direction. For easy viewing of the drawing, the wirings WL, the wirings CL, and the wirings PL included in the memory arrays 20 in the first to fifth layers are not illustrated.

The storage device 300 illustrated in FIG. 11A includes a plurality of wirings BL extending in the Z direction. The wiring BL is formed through the six layers of the memory arrays 20 and is electrically connected to the driver circuit 21. When seen from the Z direction, the plurality of wirings BL are arranged in a matrix.

In each layer of the memory arrays 20, one of the plurality of memory cells 10 included in the memory array 20 is electrically connected to one of the plurality of wirings BL. Thus, in the storage device 300 illustrated in FIG. 11A, one memory cell 10 of one memory array 20, i.e., six memory cells 10 in total, are electrically connected to one wiring BL.

A configuration in which a plurality of memory cells (memory cells 10) are electrically connected to one wiring BL is also referred to as “memory string”. Thus, it can be said that the storage device 300 illustrated in FIG. 11A includes a plurality of memory strings.

FIG. 11B is a schematic diagram of a memory string included in the storage device 300 illustrated in FIG. 11A. For easy viewing of the drawing, the wirings WL, the wirings CL, and the wirings PL electrically connected to the memory cells 10 are not illustrated in the schematic diagram of a memory string in FIG. 11B. In addition, part of an equivalent circuit of the memory string is illustrated in FIG. 11B.

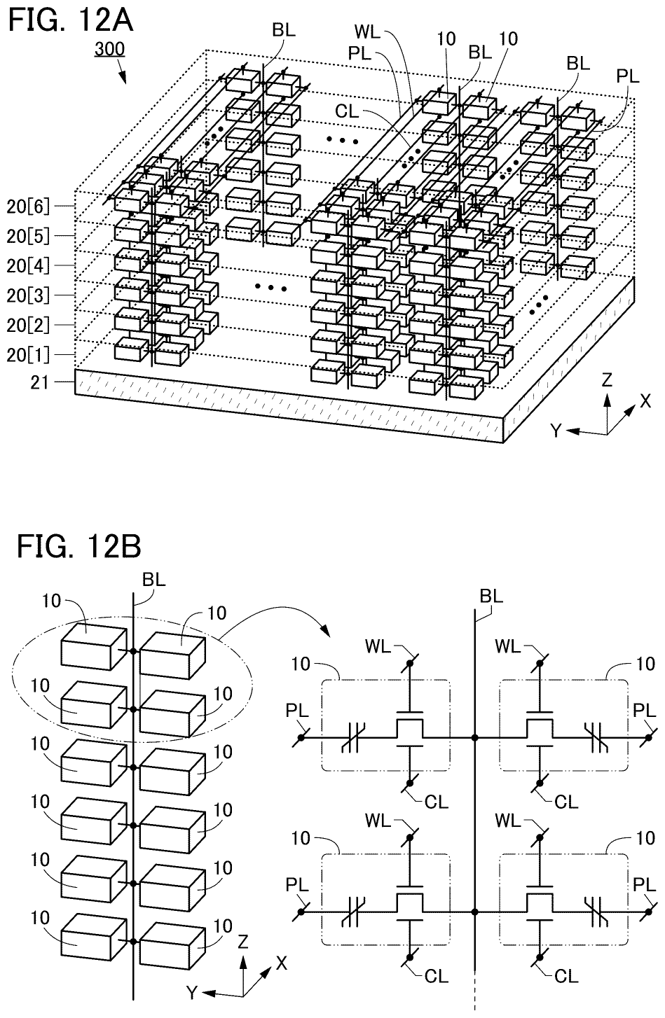

FIG. 12A is a schematic diagram illustrating a structure example of the storage device 300. The storage device 300 illustrated in FIG. 12A is a modification example of the storage device 300 illustrated in FIG. 11A. Therefore, differences from the storage device 300 illustrated in FIG. 11A are mainly described in order to reduce repeated description.

The storage device 300 illustrated in FIG. 12A is different from the storage device 300 illustrated in FIG. 11A in that two of the plurality of memory cells 10 included in each layer of the memory arrays 20 are electrically connected to one of the plurality of wirings BL. That is, 12 memory cells 10 in total are electrically connected to one wiring BL.

FIG. 12B is a schematic diagram of a memory string included in the storage device 300 illustrated in FIG. 12A. In addition, part of an equivalent circuit of the memory string is illustrated in FIG. 12B.

In the storage device 300 illustrated in FIG. 12A, the number of wirings BL can be smaller than that in the storage device 300 illustrated in FIG. 11A. Thus, the area occupied by the storage device 300 is reduced.

The memory cell 10 of one embodiment of the present invention is an FE memory, and can retain written data for a long time even when power supply is stopped. Since refresh operation required by a DRAM is unnecessary, the storage device 300 with low power consumption can be achieved.

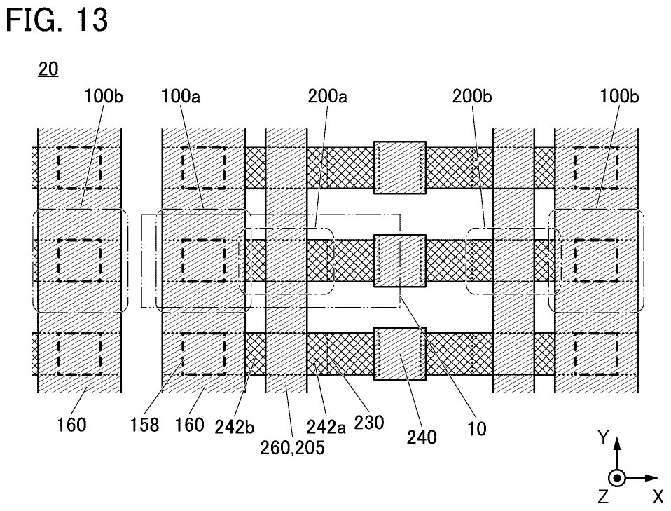

FIG. 13 illustrates an example of a layout where the memory cells 10 are arranged in a matrix to form the memory array 20. The reference numerals in FIG. 13 correspond to the reference numerals shown in FIG. 1B and the like. In the case where the minimum feature size is 20 nm, the size of the memory cell 10 in FIG. 13 can be 45 nm×125 nm. Since the area occupied by the memory cell 10 is 0.0054 μm², the density of the memory cells 10 in the storage device of this embodiment can be 185 cells/μm².

When a plurality of memory cell arrays and a driver circuit are stacked as described above, higher integration and higher storage capacity of the storage device can be achieved.

This embodiment can be combined as appropriate with any of the other embodiments and the like described in this specification.

### REFERENCE NUMERALS

10: memory cell, 20: memory array, 21: driver circuit, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 61: curve, 62: curve, 100a: capacitor, 100b: capacitor, 100: capacitor, 110a: capacitor, 110b: capacitor, 110: capacitor, 153: insulator, 156: conductor, 158: opening, 160a: conductor, 160b: conductor, 160: conductor, 200a: transistor, 200b: transistor, 200: transistor, 204a: conductor, 204b: conductor, 204: conductor, 205a: conductor, 205b: conductor, 205: conductor, 206: opening, 209: conductor, 210: insulator, 212: insulator, 214: insulator, 216: insulator, 222: insulator, 224: insulator, 230a: oxide, 230b: oxide, 230ba: region, 230bb: region, 230bc: region, 230: oxide, 240a: conductor, 240b: conductor, 240: conductor, 242a: conductor, 242a1: conductor, 242a2: conductor, 242b: conductor, 242b1: conductor, 242b2: conductor, 242: conductor, 253: insulator, 254: insulator, 258: opening, 260a: conductor, 260b: conductor, 260: conductor, 275: insulator, 280: insulator, 282: insulator, 285: insulator, 300: storage device

1. A storage device comprising:
a memory cell comprising a transistor and a capacitor; and
a conductor,
wherein the transistor comprises a source electrode, a drain electrode, a first gate insulator, and a first gate electrode,
wherein the capacitor comprises a first electrode, a dielectric over the first electrode, and a second electrode over the dielectric,
wherein a top surface and a side surface of one of the source electrode and the drain electrode of the transistor are in contact with the conductor,
wherein a top surface of the other of the source electrode and the drain electrode of the transistor is in contact with the first electrode of the capacitor, and
wherein the dielectric comprises a ferroelectric material.

2. The storage device according to claim 1, wherein the dielectric of the capacitor comprises hafnium, zirconium, and oxygen.

3. The storage device according to claim 1, wherein the dielectric of the capacitor comprises aluminum, scandium, and nitrogen.

4. The storage device according to claim 1, wherein the transistor comprises an oxide semiconductor.

5. The storage device according to claim 1,
wherein the transistor further comprises a second gate insulator and a second gate electrode,
wherein a top surface of the second gate insulator of the transistor is in contact with part of the other of the source electrode and the drain electrode of the transistor, and
wherein the second gate electrode of the transistor overlaps with the first gate electrode of the transistor with the second gate insulator of the transistor therebetween.

6. The storage device according to claim 1, comprising:
a plurality of layers each comprising the memory cell and the conductor,
wherein the plurality of layers are stacked, and
wherein the conductors in the plurality of layers overlap with each other.

7. A storage device comprising:
a memory cell comprising a transistor and a capacitor; and
a conductor,
wherein the transistor comprises a semiconductor layer, a source electrode, a drain electrode, a first gate insulator, and a first gate electrode,
wherein the capacitor comprises a first electrode, a dielectric over the first electrode, and a second electrode over the dielectric,
wherein a top surface and a side surface of one of the source electrode and the drain electrode of the transistor are in contact with the conductor,
wherein a top surface of the other of the source electrode and the drain electrode of the transistor is in contact with the first electrode of the capacitor, and
wherein the dielectric comprises a ferroelectric material.

8. The storage device according to claim 7, wherein the dielectric of the capacitor comprises hafnium, zirconium, and oxygen.

9. The storage device according to claim 7, wherein the dielectric of the capacitor comprises aluminum, scandium, and nitrogen.

10. The storage device according to claim 7, wherein the semiconductor layer comprises an oxide semiconductor.

11. The storage device according to claim 7,
wherein the transistor further comprises a second gate insulator and a second gate electrode,
wherein a top surface of the second gate insulator of the transistor is in contact with part of the other of the source electrode and the drain electrode of the transistor, and
wherein the second gate electrode of the transistor overlaps with the first gate electrode of the transistor with the semiconductor layer of the transistor therebetween.

12. The storage device according to claim 7, comprising:
a plurality of layers each comprising the memory cell and the conductor,
wherein the plurality of layers are stacked, and
wherein the conductors in the plurality of layers overlap with each other.
